(19) United States
(12) Patent Application Publication
(10) Pub. No.: US 2019/0101828 A1
(43) Pub. Date: Apr. 4, 2019

(54) RESIN COMPOSITION, CURED FILM OF SAME AND METHOD FOR MANUFACTURING SAME, AND SOLID-STATE IMAGE SENSOR

(71) Applicant: TORAY INDUSTRIES, INC., Tokyo (JP)

(72) Inventors: Toshiyasu HIBINO, Otsu-shi (JP); Yoshinori MATOBA, Otsu-shi (JP); Mitsuhito SUWA, Otsu-shi (JP)

(73) Assignee: TORAY INDUSTRIES, INC., Tokyo (JP)

(21) Appl. No.: 16/095,053

(22) PCT Filed: Apr. 17, 2017
(86) PCT No.: PCT/JP2017/015480

§ 371 Date: Oct. 19, 2018

(30) Foreign Application Priority Data
Apr. 25, 2016 (JP) 2016-086837
Jun. 30, 2016 (JP) 2016-129736

(51) Int. Cl. G03F 7/075; C08G 77/00; C09D 4/06; C09D 183/06; C09D 5/00; G03F 7/039; G03F 7/16; G03F 7/20; G03F 7/32; G03F 7/40

(52) U.S. Cl. CPC G03F 7/0758; C08G 77/80; C09D 4/06; C09D 183/06; C09D 5/00; C08G 77/70; G03F 7/162; G03F 7/168; G03F 7/2004; G03F 7/322; G03F 7/40; G03F 7/039

(57) ABSTRACT

A resin composition including a polysiloxane (A) and a solvent (B), wherein the polysiloxane (A) contains at least one partial structure represented by any of the general formulae (1) to (3), and the relationship between the film thickness X and the film thickness Y, which respectively represent the thickness of a film produced by application of the resin composition and subsequent drying at 100° C. for 3 minutes and the thickness of the film after subsequent heating at 230° C. for 5 minutes, satisfies the following inequation: (X−Y)/x≤0.05. The resin composition exhibits excellent coating properties on rugged surface and has excellent planarization properties even if the resin composition is in a form of thin film.

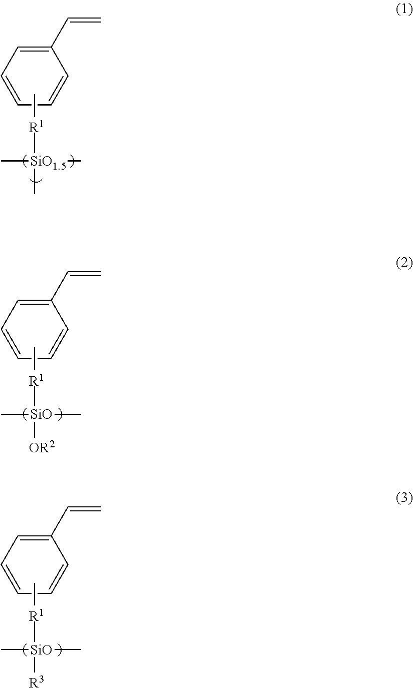

(R¹ represents a single bond or a C₁₋₄ alkyl group; R² represents a C₁₋₄ alkyl group; and R³ represents an organic group.)

### TECHNICAL FIELD

The present invention relates to a resin composition, a cured film of the resin composition and a method of manufacturing the cured film, as well as to a solid-state image sensor.

### BACKGROUND ART

The rapid development of devices such as digital camera and camera phone in recent years is accompanied by the need for miniaturized solid-state image sensors with higher pixel counts. However, miniaturization of solid-state image sensors causes a reduction in sensitivity and, thus, an optical waveguide is provided between the optical sensor and the color filter in such a solid-state image sensor to increase the light focusing efficiency and then prevent the reduction in sensitivity.

Examples of a commonly used method of manufacturing an optical waveguide include a method in which an inorganic film produced by, for example, the CVD method is processed by dry etching and a method in which a resin is applied and further processed.

Materials relevant to optical waveguide formation are required to have excellent properties such as humidity resistance, chemical resistance, coating properties on rugged surface, and planarization properties, as well as to maintain high transparency. Polysiloxane resins are used as resins that satisfy those requirements.

For example, Patent Document 1 describes a polysiloxane copolymer composed of a silane compound having a side chain containing fluorine and another silane compound having a side chain containing an acrylic group, which is a polysiloxane that has excellent coating properties and is applicable to a planar film. Moreover, Patent Document 2 describes a polysiloxane containing carboxyl groups and radical polymerizable groups as a polysiloxane which has a high degree of hardness and excellent patterning properties and is applicable to a planar film. Patent Document 3 describes a photosensitive resin composition comprising a polysiloxane that contains photopolymerizable unsaturated linking groups and carboxyl groups, and/or acid anhydride groups as a photosensitive resin composition which allows formation of vias in high resolution and will not produce sediments in a developing machine.

### PRIOR ART DOCUMENTS

### Patent Documents

Patent Document 1: JP 2013-014680 A

Patent Document 2: WO 2010/061744

Patent Document 3: JP 2015-68930 A

### SUMMARY OF THE INVENTION

### Problem to be Solved by the Invention

Thin-film optical waveguides are recently required to be thinner and thin-film planarization properties are thus becoming more important than ever before. Such thin film planarization properties are not achieved by the technologies described in Patent Documents 1 to 3.

An object of the present invention is to a resin composition that exhibits excellent coating properties on rugged surface and has excellent planarization properties even if the resin composition is in a form of thin film.

### Means for Solving the Problem

The present invention is a resin composition comprising a polysiloxane (A), wherein the polysiloxane (A) contains at least one partial structure represented by any of the general formulae (1) to (3), and the molar content of styryl groups contained in the polysiloxane (A) is in the range of not less than 40% by mole to not more than 99% by mole relative to 100% by mole of the Si atoms:

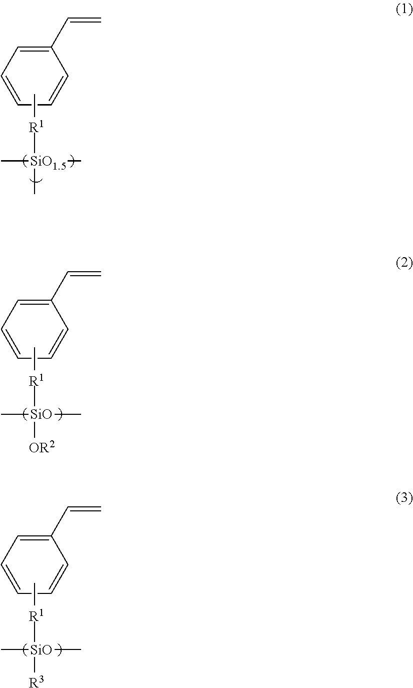

(wherein R¹ represents a single bond or a C₁₋₄ alkyl group; R² represents a hydrogen atom or a C₁₋₄ alkyl group; and R³ represents an organic group).

### Advantageous Effect of the Invention

The resin composition according to the present invention exhibits excellent coating properties on rugged surface and has excellent planarization properties even if the resin composition is in a form of thin film.

### BRIEF DESCRIPTION OF THE DRAWINGS

FIG. 1 is a top view of a substrate which has a concave-convex structure patterned on a support substrate.

FIG. 2 is a cross-sectional view of a substrate which has a concave-convex structure patterned on a support substrate.

FIG. 3 is a cross-sectional view of a substrate having a concave-convex structure and coated with a resin film.

FIG. 4 is a cross-sectional view of a substrate having a concave-convex structure and coated with a resin film.

FIG. 5 is a top view of a substrate which has a concave-convex structure patterned on a silicon wafer.

FIG. 6 is a cross-sectional view of a substrate which has a concave-convex structure wherein a cured film pattern is formed on a silicon wafer.

FIG. 7 is a cross-sectional view of a state wherein a silicon wafer having a cured film pattern is coated with a resin film.

FIG. 8 is a process flow chart showing the production of a cured film by using a resin composition according to an embodiment of the present invention.

FIG. 9 is a process flow chart showing the production of a cured film by using a resin composition according to an embodiment of the present invention.

FIG. 10 is a process flow chart showing the production of a cured film by using a resin composition according to an embodiment of the present invention.

### DETAILED DESCRIPTION OF THE INVENTION

Preferred embodiments of a resin composition according to the present invention, a cured film of the resin composition and a method of manufacturing the cured film, as well as a solid-state image sensor will be described below in detail. However, the present invention is not limited to the following embodiments but the present invention may be practiced with various modifications depending on the purposes and uses.

### <Resin Composition>

The resin composition according to an embodiment of the present invention is a resin composition comprising a polysiloxane (A), wherein the polysiloxane (A) contains at least one partial structure represented by any of the general formulae (1) to (3), and the molar content of styryl groups contained in the polysiloxane (A) is in the range of not less than 40% by mole to not more than 99% by mole relative to 100% by mole of the Si atoms.

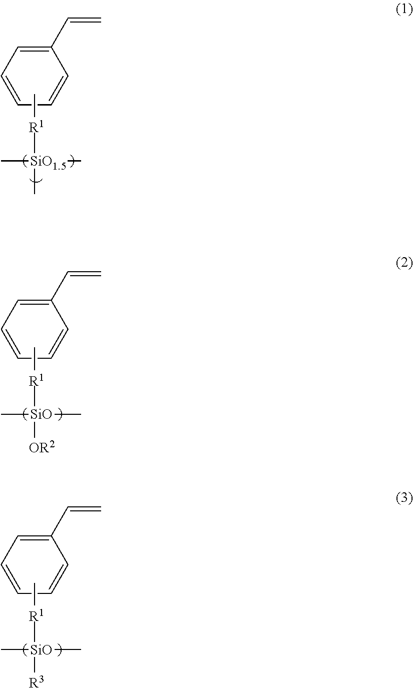

R¹ represents a single bond or a C₁₋₄ alkyl group, and R² represents a hydrogen atom or a C₁₋₄ alkyl group, and R³ represents an organic group.

For planarization of a surface having a concave-convex structure with a thin film, the inventors focused their attention on thermal shrinkage of a planarization material.

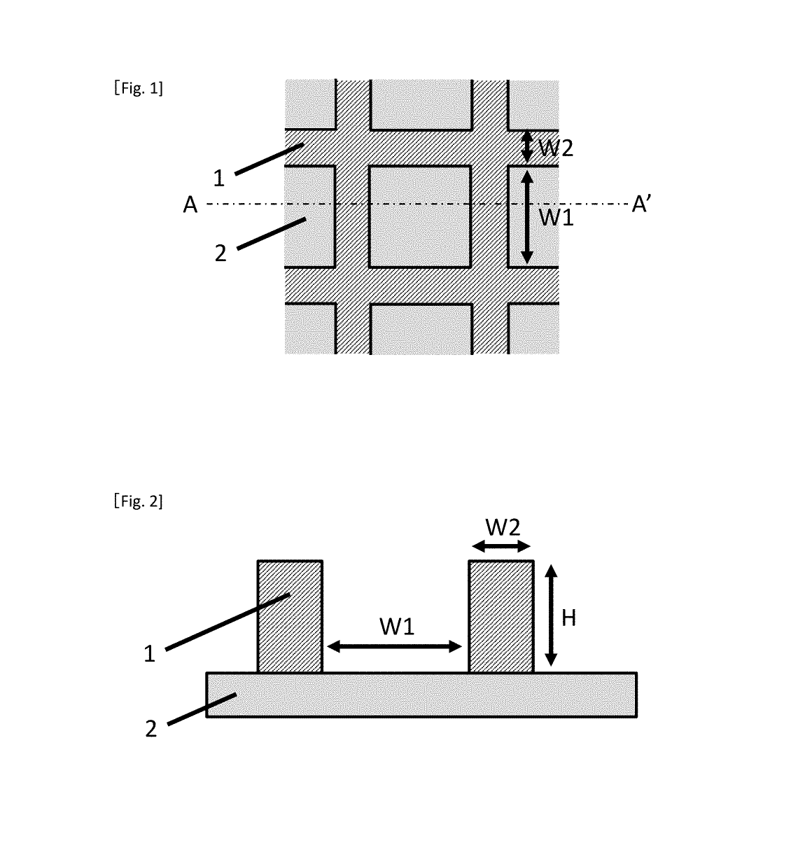

The concave-convex structure as used herein refers to a concave-convex structure, for example, as shown in FIG. 1 and FIG. 2. FIG. 1 is a top view of a substrate having a concave-convex structure (hereinafter referred to as “rugged substrate”) and FIG. 2 is a cross-sectional view taken along line A-A′ in FIG. 1. The pattern 1 is a convex portion, while the opening in the pattern, namely the region where the support substrate 2 is exposed is a concave portion. This concave-convex structure has steps with a depth H, a width W1 of concave portions and a width W2 of convex portions. The following conditions are satisfied:

W1≥W2,

H≥W2,

0.1 μm≤H≤5.0 μm, and

0.1 μm≤W1≤5.0 μm.

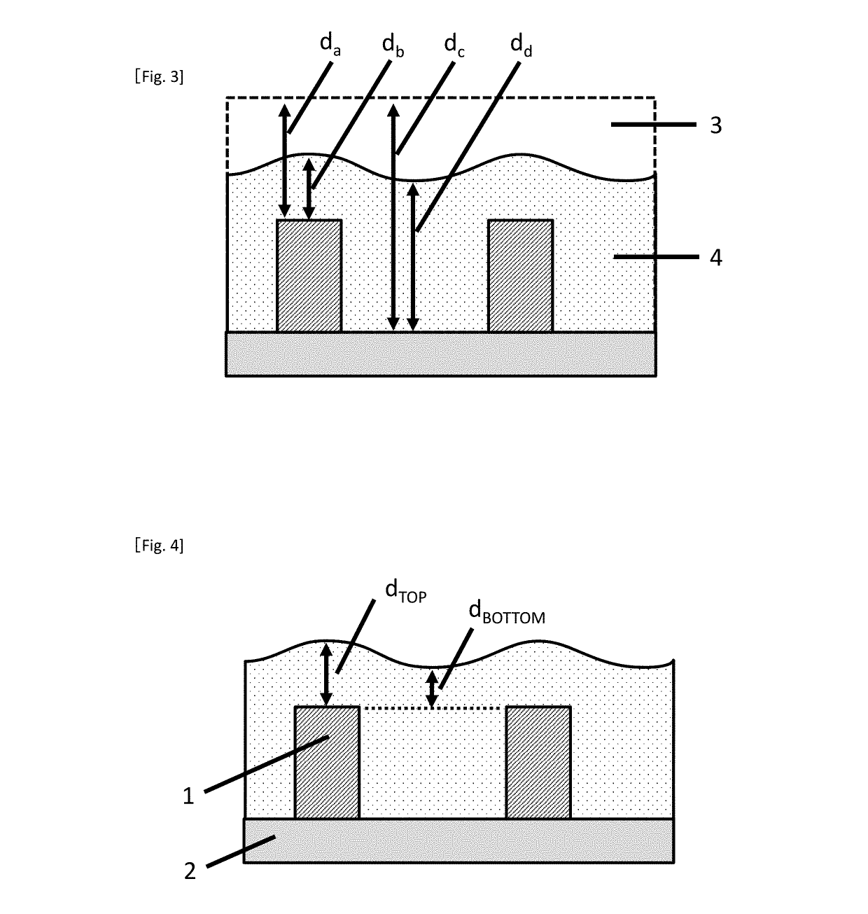

A cured film obtained by curing a resin composition applied on such a rugged substrate by a technique such as spin coating or slit coating generally has a cross section as shown in FIG. 3. In this figure, dₐ represents the resin film thickness at a convex portion prior to curing, and d_{b} represents the resin film thickness at the convex portion post curing, and d_{c} represents the resin film thickness at a concave portion prior to curing, and d_{d} represents the resin film thickness at the concave portion post curing.

The relationship among those film thickness values satisfies the following conditions: dₐ<d_{c} and d_{b}<d_{d}. The ratio of film shrinkage during curing is not different between shrinkage at a convex portion and at a concave portion and those values thus satisfy the inequation (dₐ−d_{b})<(d_{c}−d_{d}). Thus, a larger change in film thickness occurs to the concave portion and a depression is consequently formed. A material with a higher thermal shrinkage ratio causes a large difference between the values (dₐ−d_{b}) and (d_{c}−d_{d}) and thus forms deep depressions, whereas a material with a lower thermal shrinkage ratio causes a small difference between the values (dₐ−d_{b}) and (d_{c}−d_{d}) and thus forms shallow depressions, which in turn promotes the formation of a flat surface.

In cases where the thickness of the resin film on the rugged substrate is large enough, the free volume of the resin is increased, which causes the flow of the resin to occur simultaneously with thermal shrinkage and may improve the flatness of the substrate. However, a planarization material used for an optical waveguide in a solid-state image sensor is required to be a thin film, for the purpose of shortening the optical path length. Shortening of the optical path length can reduce the loss of light and consequently improve the sensitivity of the solid-state image sensor.

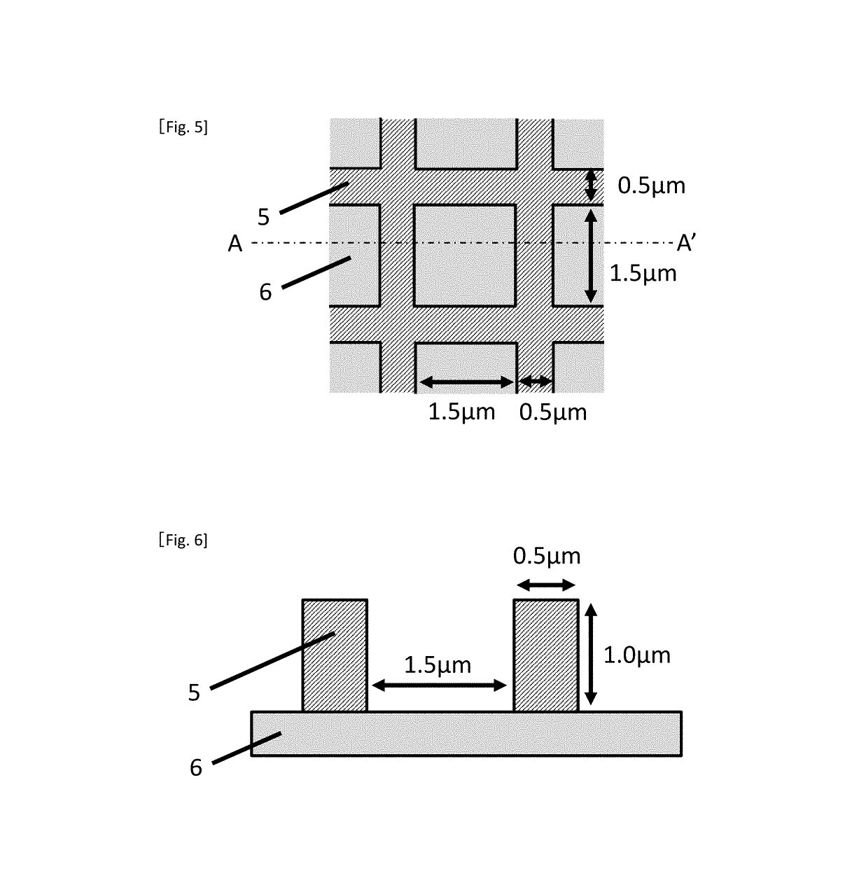

The film thickness required for optical waveguides in solid-state image sensors may vary depending on the size of each optical waveguide and preferably satisfies the following inequation, as seen in the cross-sectional view in FIG. 4: d_{TOP}/H≤0.3. The d_{TOP} refers to the film thickness of an optical waveguide at convex portions in reference to the height of a convex portion in the rugged substrate and is measured by the method described below. The flow of a resin hardly occurs during curing when the d_{TOP} value is within the range represented by the above inequation, which in turn increases the influence of film shrinkage and easily reduces the flatness of the surface. Thus, a material with a low thermal shrinkage ratio is required.

In the required flatness, the d_{TOP} and the d_{BOTTOM} shown in FIG. 4 are desired to satisfy the following inequation: d_{BOTTOM}/d_{TOP}≥0.7. The d_{BOTTOM} refers to the film thickness of an optical waveguide at concave portions in reference to the height of a convex portion in the rugged substrate and is measured by the method described below.

A notch is formed on the rugged substrate coated with the cured film of the resin composition and the resulting substrate is cleaved off to measure the d_{TOP} and the d_{BOTTOM} on a field emission-type scanning electron microscope (FE-SEM). The d_{TOP} and the d_{BOTTOM} in optical waveguides for solid-state image sensors can be measured at a magnification of approximately 10,000 to 50,000 times. The film thickness is measured at each center of convex and concave portions at three different positions and the average values are taken as the d_{TOP} and the d_{BOTTOM}. A position at the center of the substrate and positions adjacent to the left and right sides of the central position are selected as the above-described three positions each for convex and concave portions.

The inventors focused their attention on thermal shrinkage of a resin composition and found that the ratio d_{BOTTOM}/d_{TOP} approached to 1 and a cured film with a remarkably flat surface was obtained when a resin composition which showed a low rate of film thickness change before and after curing in the formation of a cured film was applied on a rugged substrate and cured.

Specifically, a cured film which shows a low rate of film thickness change and has a remarkably flat surface can be obtained by applying a resin composition comprising a polysiloxane (A) which contains at least one partial structure represented by any of the above-described general formulae (1) to (3), wherein the molar content of styryl groups contained in the polysiloxane (A) is in the range of not less than 40% by mole to not more than 99% by mole relative to 100% by mole of the Si atoms. In the resin composition according to an embodiment of the present invention, the rate of film thickness change before and after heating at 230° C. for 5 minutes is preferably not more than 5%.

As described below, the resin composition according to an embodiment of the present invention may be a photosensitive composition which is applied on a rugged substrate to form a coated film and then exposed to light, developed, and subsequently cured, or a non-photosensitive composition which is cured without the above-described exposure and development processes. In either case, the relationship between the film thickness prior to curing and post curing is important to achieve the effects of the present invention.

In the present invention, the rate of film thickness change before and after heating a resin composition at 230° C. for 5 minutes is defined as described below.

In cases where the resin composition is a non-photosensitive composition, the relationship between the film thickness X and the film thickness Y, which respectively represent the thickness of a film produced by application of the resin composition and subsequent drying at 100° C. for 3 minutes and the thickness of the film after subsequent heating at 230° C. for 5 minutes, satisfies the following inequation: (X−Y)/x≤0.05.

In cases where the resin composition is a photosensitive composition, the resin composition is applied, dried at 100° C. for 3 minutes, and then exposed to i-line light at an exposure dose of 400 mJ/cm² with an i-line stepper exposure machine. Subsequently, the resin composition is developed in a shower of 0.4% by weight tetramethylammonium hydroxide in water for 90 seconds and then rinsed in water for 30 seconds. In this case, the relationship between the film thickness X′ and the film thickness Y, which respectively represent the thickness of a film produced by the above-described procedure and subsequent heat-drying at 100° C. for 3 minutes and the thickness of the film after subsequent heating at 230° C. for 5 minutes, satisfies the following inequation: (X′−Y)/X′≤0.05.

The film thickness vales X, X′ and Y are values obtained when a resin composition is applied on a flat substrate. The resin composition according to an embodiment of the present invention as a non-photosensitive composition is a resin composition that allows the relationship represented by the inequation (X−Y)/x≤0.05 to be satisfied when the resin composition is applied on a flat substrate under conditions where the value X falls within the range of 0.95 to 1.1 μm. The resin composition as a photosensitive composition is a resin composition that allows the relationship represented by the inequation (X′−Y)/X′≤0.05 to be satisfied when the resin composition is applied on a flat substrate, exposed to light, and developed under conditions where the value X′ falls within the range of 0.95 to 1.1 μm.

The film thickness vales X, X′ and Y are values measured as described below. The values X or X′ and Y are preferably measured at the same positions and a contactless measurement method for the film thickness is used not to damage measurement positions. For example, a resin composition is applied on a substrate such as silicon wafer and the resulting film is marked with three to five circles having a diameter of around 5 mm by using forceps and the film thickness is then measured at the center of each circle by using the Lambda Ace STM-602 (tradename; manufactured by Dainippon Screen Mfg. Co., Ltd.) and the average of the measured values is considered as the film thickness value.

### <Polysiloxane (A)>

Many polysiloxanes have low glass transition temperatures (Tgs), particularly glass transition temperatures (Tgs) of 100° C. or lower. Thus, a resin composition containing a polysiloxane is easily flowable in the coating process and is used as a planarization material. The polysiloxane according to the present invention is a polysiloxane that serves to reduce thermal shrinkage of a resin composition containing the polysiloxane and thus the cured film after curing has little reduction in the flatness of the resin composition after coating.

The polysiloxane used in the present invention contains at least one partial structure represented by any of the above-described general formulae (1) to (3). Each of the partial structures includes a styryl group (a-1).

The presence of styryl groups (a-1) in the polysiloxane can reduce film shrinkage upon thermal curing. The intermolecular Diels-Alder reaction of compounds substituted with styryl groups (a-1) abstracts a proton from the tertiary carbon atom to generate a radical in the course of dimerization and such compounds are thus prone to thermal radical polymerization. A very small volume reduction occurs in films cured by radical polymerization of styrene and allows the films to maintain excellent flatness after film coating, as compared to films cured by condensation of siloxane.

The molar content of styryl groups (a-1) contained in the polysiloxane is in the range of not less than 40% by mole to not more than 99% by mole relative to 100% by mole of the Si atoms. The effect to reduce film shrinkage upon thermal curing is increased and the excellent planarization properties are exhibited when the molar content is within the above-described range.

The molar content of styryl groups (a-1) contained in the polysiloxane can be calculated from the integrated peak area ratio of the peak of styryl group to all peaks from polysiloxane in ¹H-NMR and/or ²⁹Si-NMR spectra.

Preferably, the polysiloxane (A) further contains at least one partial structure represented by any of the following general formulae (7) to (9) in the polysiloxane (A). Each of the partial structures includes a hydrophilic group (a-3).

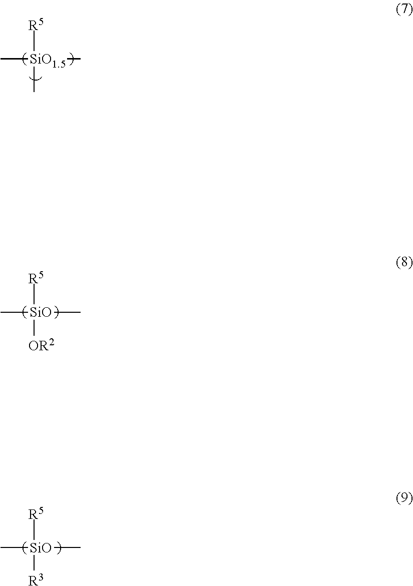

R⁵ represents a hydrocarbon group having an epoxy group, hydroxyl group, urea group, urethane group, amide group, carboxyl group, or carboxylic anhydride. R² represents a hydrogen atom or a C₁₋₄ alkyl group, and R³ represents an organic group.

Preferably, the polysiloxane (A) further contains at least one partial structure represented by any of the following general formulae (4) to (6) in the polysiloxane (A). Each of the partial structures includes a (meth)acryloyl group (a-2).

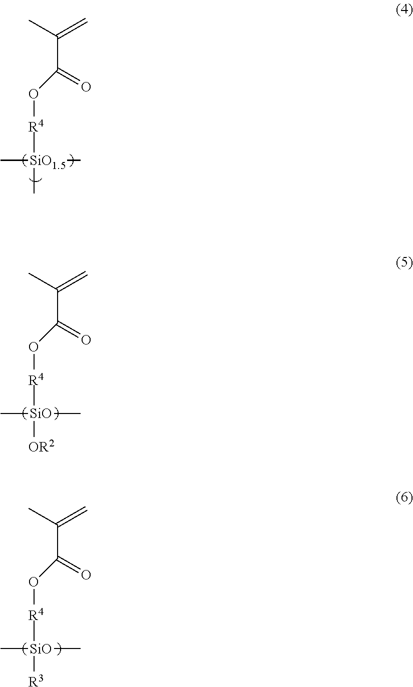

R⁴ each independently represents a single bond or a C₁₋₄ alkylene group, and R² represents a hydrogen atom or a C₁₋₄ alkyl group, and R³ represents an organic group.

The presence of styryl groups (a-1) contributes to the reduction in film shrinkage upon thermal curing, while increasing the hydrophobicity of the resin composition, which causes poor wetting and spreading of the resin composition to occur near the periphery of substrates and potentially results in decrease in yield. Hydrophilic groups (a-3) are preferably introduced to evenly apply the resin composition on the substrate from edge to edge and to increase the yield. Thus, the wetting on substrates is improved in the resin composition by introducing hydrophilic groups (a-3) into the polysiloxane, which are a type of hydrophilic group contained in a partial structure represented by any of the above-described formulae (7) to (9). Consequently, the yield can be increased by preventing incomplete coating of substrates near their periphery.

Furthermore, introduction of (meth)acryloyl groups (a-2) into the polysiloxane easily makes a difference in the cure degree of the resin composition between exposed and unexposed portions and enables patterning with high resolution and reduced post-development residue production. The hydrophilic group (a-3) is not limited to a particular group but hydrophilic groups represented by the structures indicated below are preferable. Raw materials for polysiloxanes containing any of the hydrophilic groups (a-3), that is, alkoxysilane compounds are commercially available and easily obtainable.

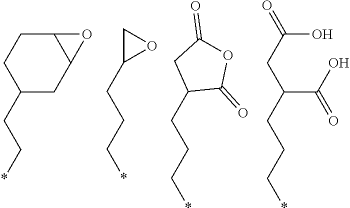

The asterisk indicated in each structural formula indicates the point of attachment to a Si atom. In cases where a pattern is formed through a photolithography process, the hydrophilic group is preferably, for example, a hydrocarbon group having a structure based on a carboxylic acid or a carboxylic anhydride and is more preferably a hydrocarbon group having a structure based on succinic acid or succinic anhydride, among others.

The molar content of (meth)acryloyl groups (a-2) in the polysiloxane is preferably in the range of not less than 15% by mole to not more than 40% by mole relative to 100% by mole of the Si atoms.

The molar content of hydrophilic groups (a-3) in the polysiloxane is preferably in the range of not less than 10% by mole to not more than 20% by mole relative to 100% by mole of the Si atoms, from the viewpoint of post-development residue and adhesion to a substrate.

The molar contents of (meth)acryloyl groups (a-2) and hydrophilic groups (a-3) in the polysiloxane can be calculated similarly to styryl groups (a-1) from the integrated peak area ratio of the peak of (meth)acryloyl group or hydrophilic group to all peaks from polysiloxane in ¹H-NMR and/or ²⁹Si-NMR spectra.

The polysiloxane containing any of the partial structures represented by the above-described formulae (1) to (3) and any of the partial structures represented by the above-described formulae (4) to (6) is obtainable by hydrolysis and polycondensation of plural alkoxysilane compounds including those represented by the general formulae (10) and (11).

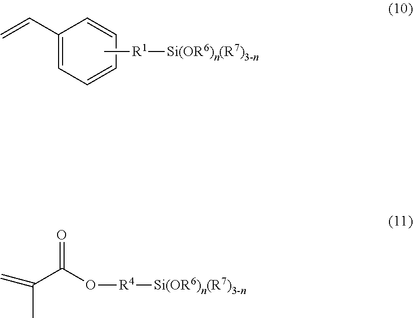

R¹ and R⁴ each represent a single bond or a C₁₋₄ alkylene group, and R⁶ represents a C₁₋₄ alkyl group, and R⁷ represents an organic group.

Moreover, the polysiloxane containing any of the partial structures represented by the above-described formulae (7) to (9) is obtainable by hydrolysis and polycondensation of plural alkoxysilane compounds including that represented by the general formula (12).

R⁸—Si(OR⁶)ₘ(R⁷)₃₋ₘ (12)

R⁶ represents a C₁₋₄ alkyl group, and R⁷ represents an organic group, and R⁸ represents an organic group, and R⁸ represents an epoxy group, hydroxyl group, urea group, urethane group, amide group, carboxyl group, or carboxylic anhydride. The letter m represents 2 or 3, and the letter n represents 2 or 3.

As specific examples of the alkoxysilane compound represented by the general formula (10), for example, styryltrimethoxysilane, styryltriethoxysilane, styryltri(methoxyethoxy)silane, styryltri(propoxy)silane, styryltri(butoxy)silane, styrylmethyldimethoxysilane, styrylethyldimethoxysilane, styrylmethyldiethoxysilane, and styrylmethyldi(methoxyethoxy)silane are preferably used.

Specific examples of the organosilane compound containing a (meth)acryloyl group represented by the general formula (11) include γ-acryloylpropyltrimethoxysilane, γ-acryloylpropyltriethoxysilane, γ-acryloylpropyltri(methoxyethoxy)silane, γ-methacryloylpropyltrimethoxysilane, γ-methacryloylpropyltriethoxysilane, γ-methacryloylpropyltri(methoxyethoxy)silane, γ-methacryloylpropylmethyldimethoxysilane, γ-methacryloylpropylmethyldiethoxysilane, γ-acryloylpropylmethyldimethoxysilane, γ-acryloylpropylmethyldiethoxysilane, and γ-methacryloylpropyl(methoxyethoxy)silane. Two or more of them may be used. Among those, γ-acryloylpropyltrimethoxysilane, γ-acryloylpropyltriethoxysilane, γ-methacryloylpropyltrimethoxysilane, and γ-methacryloylpropyltriethoxysilane are preferable from the viewpoint of the hardness of the cured film and of improvement of sensitivity during pattern formation.

Specific examples of the alkoxysilane compound represented by the general formula (12) include organosilane compounds including a structure based on a carboxylic anhydride represented by any of the following general formulae (13) to (15), epoxy group-containing organosilane compounds, urethane group-containing organosilane compounds represented by the general formula (16) below, and urea group-containing organosilane compounds represented by the general formula (17) below.

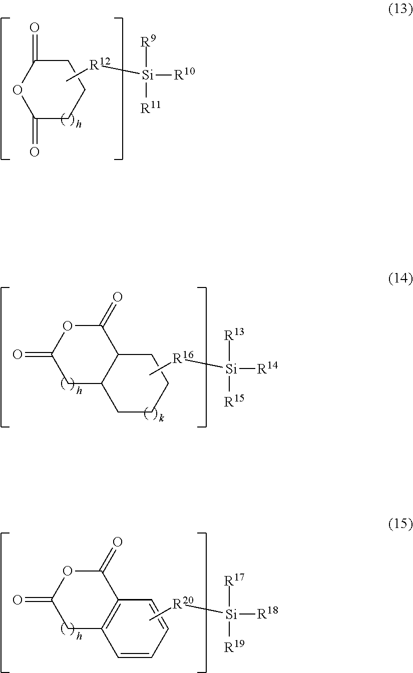

In the general formulae (13) to (15), R⁹ to R¹¹, R¹³ to R¹⁵, and R¹⁷ to R¹⁹ each represent a C₁₋₆ alkyl group, C₁₋₆ alkoxy group, phenyl group, phenoxy group, or C2-6 alkylcarbonyloxy group. R¹², R¹⁶ and R²⁰ each represent a single bond, or a C₁₋₁₀ linear aliphatic hydrocarbon group, C₃₋₁₆ cyclic aliphatic hydrocarbon group, C₂₋₆ alkylcarbonyloxy group, carbonyl group, ether group, ester group, amide group, aromatic group, or divalent group substituted with any of these groups. Optionally, these groups may be substituted with a substituent. The letters h and k each represent an integer of 0 to 3.

Specific examples of R¹², R¹⁶, and R²⁰ include —C₂H₄—, —C₃H₆—, —C₄H₈—, —O—, —C₃H₆OCH₂CH (OH) CH₂O₂C—, —CO—, —CO₂—, —CONH—, and organic groups as indicated below.

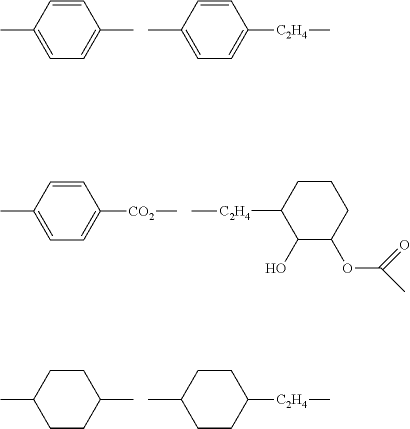

Specific examples of the organosilane compound represented by the general formula (13) include [3-(trimethoxysilyl)propyl]succinic anhydride, [3-(triethoxysilyl)propyl]succinic anhydride, and [3-(triphenoxysilyl)propyl]succinic anhydride.

Specific examples of the organosilane compound represented by the general formula (14) include 3-(trimethoxysilyl)propylcyclohexane-dicarboxylic anhydride.

Specific examples of the organosilane compound represented by the general formula (15) include 3-(trimethoxysilyl)propylphthalic anhydride.

Examples of the epoxy group-containing organosilane compounds include (glycidoxymethyl)methyldimethoxysilane, (glycidoxymethyl)methyldiethoxysilane, α-(glycidoxyethyl)methyldimethoxysilane, α-(glycidoxyethyl)methyldiethoxysilane, β-(glycidoxyethyl)methyldimethoxysilane, β-(glycidoxyethyl)methyldiethoxysilane, α-(glycidoxypropyl)methyldimethoxysilane, α-(glycidoxypropyl)methyldiethoxysilane, β-(glycidoxypropyl)methyldimethoxysilane, β-(glycidoxypropyl)methyldiethoxysilane, γ-(glycidoxypropyl)methyldimethoxysilane, γ-(glycidoxypropyl)methyldiethoxysilane, γ-(glycidoxypropyl)methyldipropoxysilane, β-(glycidoxypropyl)methyldibutoxysilane, γ-(glycidoxypropyl)ethyldimethoxysilane, γ-(glycidoxypropyl)ethyldiethoxysilane, γ-(glycidoxypropyl)vinyldimethoxysilane, γ-(glycidoxypropyl)vinyldiethoxysilane, (glycidoxymethyl)trimethoxysilane, (glycidoxymethyl)triethoxysilane, α-(glycidoxyethyl)trimethoxysilane, α-(glycidoxyethyl)triethoxysilane, β-(glycidoxyethyl)trimethoxysilane, β-(glycidoxyethyl)triethoxysilane, α-(glycidoxypropyl)trimethoxysilane, α-(glycidoxypropyl)triethoxysilane, γ-(glycidoxypropyl)trimethoxysilane, β-(glycidoxypropyl)triethoxysilane, γ-(glycidoxypropyl)trimethoxysilane, γ-(glycidoxypropyl)triethoxysilane, γ-(glycidoxypropyl)tripropoxysilane, γ-(glycidoxypropyl)triisopropoxysilane, γ-(glycidoxypropyl)tributoxysilane, α-(glycidoxybutyl)trimethoxysilane, α-(glycidoxybutyl)triethoxysilane, β-(glycidoxybutyl)trimethoxysilane, β-(glycidoxybutyl)triethoxysilane, γ-(glycidoxybutyl)trimethoxysilane, γ-(glycidoxybutyl)triethoxysilane, δ-(glycidoxybutyl)trimethoxysilane, δ-(glycidoxybutyl)triethoxysilane, (3,4-epoxycyclohexyl)methyltrimethoxysilane, (3,4-epoxycyclohexyl)methyltriethoxysilane, (3,4-epoxycyclohexyl)methyltrimethoxysilane, (3,4-epoxycyclohexyl)methyltriethoxysilane, 2-(3,4-epoxycyclohexyl)ethyltripropoxysilane, 2-(3,4-epoxycyclohexyl)ethyltributoxysilane, 2-(3,4-epoxycyclohexyl)ethyltrimethoxysilane, 2-(3,4-epoxycyclohexyl)ethyltriethoxysilane, 2-(3,4-epoxycyclohexyl)ethyltriphenoxysilane, 3-(3,4-epoxycyclohexyl)propyltrimethoxysilane, 3-(3,4-epoxycyclohexyl)propyltriethoxysilane, 4-(3,4-epoxycyclohexyl)butyltrimethoxysilane, and 4-(3,4-epoxycyclohexyl)butyltriethoxysilane.

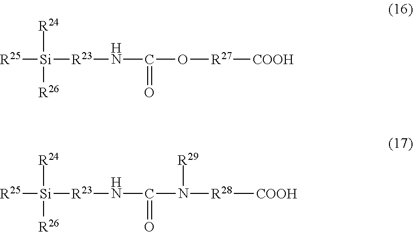

R²³, R²⁷, and R²⁸ each represent a C₁₋₂₀ divalent organic group. R²⁹ represents a hydrogen atom or a C₁₋₃ alkyl group. R²⁴ to R²⁶ each represent a C₁₋₆ alkyl group, C₁₋₆ alkoxyl group, phenyl group, phenoxy group, C₂₋₆ alkylcarbonyloxy group, or any substitution product thereof. However, at least one of R²⁴ to R²⁶ is an alkoxy group, phenoxy group, or acetoxy group.

In the above-described general formulae (16) and (17), preferred examples of R²⁸ and R²⁷ include hydrocarbon groups such as methylene group, ethylene group, n-propylene group, n-butylene group, phenylene group, —CH₂—C₆H₄—CH₂—, and —CH₂—C₆H₄—. Among those, hydrocarbon groups containing an aromatic ring such as phenylene group, —CH₂—C₆H₄—CH₂—, and —CH₂—C₆H₄— are preferable in terms of thermal resistance.

In the above-described general formula (17), R²⁹ preferably represents a hydrogen or methyl group from the viewpoint of reactivity. In the above-described general formulae (16) and (17), specific examples of R²⁸ include hydrocarbon groups such as methylene group, ethylene group, n-propylene group, n-butylene group, and n-pentylene group, and oxymethylene group, oxyethylene group, oxy-n-propylene group, oxy-n-butylene group, and oxy-n-pentylene group. Among those, methylene group, ethylene group, n-propylene group, n-butylene group, oxymethylene group, oxyethylene group, oxy-n-propylene group, and oxy-n-butylene group are preferable from the viewpoint of ease of synthesis.

In the above-described general formulae (16) and (17), specific examples of the alkyl groups in R²⁴ to R²⁶ include methyl group, ethyl group, n-propyl group, and isopropyl group. Among those, methyl group or ethyl group is preferable from the viewpoint of ease of synthesis. Moreover, specific examples of the alkoxy group include methoxy group, ethoxy group, n-propoxy group, and isopropoxy group. Among those, methoxy group or ethoxy group is preferable from the viewpoint of ease of synthesis. Moreover, examples of the substituents in the substitution products include methoxy group and ethoxy group. Specific examples of the substitution products include 1-methoxypropyl group and methoxyethoxy group.

The urea group-containing organosilane compounds represented by the above-described general formula (17) can be obtained by a known urea-forming reaction between any aminocarboxylic acid compound represented by the general formula (18) below and any isocyanate group-containing organosilane compound represented by the general formula below (19). Moreover, the urethane group-containing organosilane compounds represented by the above-described general formula (16) can be obtained by a known urethane-forming reaction between any hydroxycarboxylic acid compound represented by the general formula (20) below and any isocyanate group-containing organosilane compound represented by the general formula (19) below.

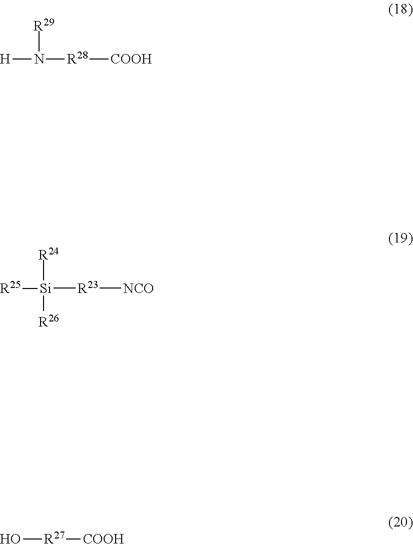

R²³, R²⁷, and R²⁸ each represent a C₁₋₂₀ divalent organic group. R²⁹ represents a hydrogen atom or a C₁₋₃ alkyl group. R²⁴ to R²⁶ each represent a C₁₋₆ alkyl group, C₁₋₆ alkoxyl group, phenyl group, phenoxy group, C2-6 alkylcarbonyloxy group, or any substitution product thereof. However, at least one of R²⁴ to R²⁶ is an alkoxy group, phenoxy group, or acetoxy group. Preferred examples of R²³ to R²⁹ are as described above for R²³ to R²⁹ in the general formulae (16) and (17).

Any of silane compounds other than the above-described silane compounds may be involved in the synthesis of the polysiloxane. These alkoxysilane compounds include, as trifunctional alkoxysilane compounds, for example, methyltrimethoxysilane, methyltriethoxysilane, methyltripropoxysilane, methyltriisopropoxysilane, methyltributoxysilane, ethyltrimethoxysilane, ethyltriethoxysilane, hexyltrimethoxysilane, octadecyltrimethoxysilane, octadecyltriethoxysilane, phenyltrimethoxysilane, phenyltriethoxysilane, phenyltriisopropoxysilane, 3-aminopropyltriethoxysilane, N-(2-aminoethyl)-3-aminopropyltrimethoxysilane, 3-chloropropyltrimethoxysilane, 3-(N,N-diglycidyl)aminopropyltrimethoxysilane, 3-(glycidoxy)propyltrimethoxysilane, vinyltrimethoxysilane, vinyltriethoxysilane, γ-methacryloxypropyltrimethoxysilane, γ-methacryloxypropyltriethoxysilane, γ-aminopropyltrimethoxysilane, γ-aminopropyltriethoxysilane, N-β-(aminoethyl)-γ-aminopropyltrimethoxysilane, β-cyanoethyltriethoxysilane, trifluoromethyltrimethoxysilane, trifluoromethyltriethoxysilane, trifluoropropyltrimethoxysilane, trifluoropropyltriethoxysilane, perfluoropropylethyltrimethoxysilane, perfluoropropylethyltriethoxysilane, perfluoropentylethyltrimethoxysilane, perfluoropentylethyltriethoxysilane, tridecafluorooctyltrimethoxysilane, tridecafluorooctyltriethoxysilane, tridecafluorooctyltripropoxysilane, tridecafluorooctyltriisopropoxysilane, heptadecafluorodecyltrimethoxysilane, and heptadecafluorodecyltriethoxysilane.

Those alkoxysilane compounds include, as difunctional alkoxysilane compounds, for example, dimethyldimethoxysilane, dimethyldiethoxysilane, diphenyldimethoxysilane, diphenyldiethoxysilane, methylphenyldimethoxysilane, methylvinyldimethoxysilane, methylvinyldiethoxysilane, γ-(glycidoxypropyl)methyldimethoxysilane, γ-aminopropylmethyldimethoxysilane, γ-aminopropylmethyldiethoxysilane, N-(2-aminoethyl)-3-aminopropylmethyldimethoxysilane, γ-methacryloxypropylmethyldimethoxysilane, γ-methacryloxypropylmethyldiethoxysilane, trifluoropropylmethyldimethoxysilane, trifluoropropylmethyldiethoxysilane, trifluoropropylethyldimethoxysilane, trifluoropropylethyldiethoxysilane, trifluoropropylvinyldimethoxysilane, trifluoropropylvinyldiethoxysilane, heptadecafluorodecylmethyldimethoxysilane, 3-chloropropylmethyldimethoxysilane, 3-chloropropylmethyldiethoxysilane, cyclohexylmethyldimethoxysilane, and octadecylmethyldimethoxysilane.

Among those trifunctional alkoxysilane compounds, for example, methyltrimethoxysilane, methyltriethoxysilane, phenyltrimethoxysilane, and phenyltriethoxysilane are preferable from the viewpoint of chemical resistance of the resulting coated film.

Among those difunctional alkoxysilane compounds, dimethyldialkoxysilanes are preferably used for the purpose of imparting flexibility to the resulting coated film.

Additionally, those alkoxysilane compounds include, as tetrafunctional alkoxysilane compounds, for example, tetramethoxysilane and tetraethoxysilane.

Those alkoxysilane compounds may be used singly or in combination of two or more.

In the resin composition, the content of a product (a siloxane compound) from a hydrolysis and condensation reaction of an alkoxysilane(s) is preferably not less than 10% by weight and more preferably not less than 20% by weight relative to the total amount of solids remaining after removal of a solvent from the resin composition. Moreover, the content of the product is more preferably not more than 80% by weight. The presence of the siloxane compound within the above-described range can further increase the transmittance and the crack resistance of a coated film.

For the hydrolysis reaction, it is preferred to add an acid catalyst and water to the above-described alkoxysilane compound(s) in a solvent over 1 to 180 minutes and then to allow the reaction to proceed at a temperature from room temperature to 110° C. for 1 to 180 minutes. The hydrolysis reaction under such conditions can prevent the reaction from proceeding rapidly. The reaction temperature is more preferably from 40 to 105° C.

After obtaining a silanol compound by the hydrolysis reaction, the reaction liquid is preferably heated at a temperature of not lower than 50° C. and not higher than the boiling point of the solvent for 1 to 100 hours to perform the condensation reaction. Moreover, the siloxane compound obtained by the condensation reaction may be heated again or supplemented with a base catalyst to increase its polymerization degree.

Various conditions for the hydrolysis reaction can be appropriately selected in view of the scale of the reaction, the size and the shape of the reaction vessel, and the like. Physical properties suitable for the application of interest can be obtained by appropriately selecting, for example, the concentration of the acid, the reaction temperature, and the reaction time.

Examples of the acid catalyst used in the hydrolysis reaction include acid catalysts such as hydrochloric acid, acetic acid, formic acid, nitric acid, oxalic acid, hydrochloric acid, sulfuric acid, phosphoric acid, polyphosphoric acid, a polyvalent carboxylic acid, or any anhydride thereof, and ion exchange resins. In particular, an acidic aqueous solution prepared by using formic acid, acetic acid, or phosphoric acid is preferable.

The preferred content of the acid catalyst is preferably not less than 0.05 parts by weight and more preferably not less than 0.1 parts by weight and is also preferably not more than 10 parts by weight and more preferably not more than 5 parts by weight relative to 100 parts by weight of all the alkoxysilane compounds used in the hydrolysis reaction. The total amount of all alkoxysilane compounds as used herein refers to the amount of the alkoxysilane compounds, including hydrolysis products and condensation products therefrom, and the same shall apply hereinafter. An acid catalyst in an amount of not less than 0.05 parts by weight allows hydrolysis to proceed smoothly, whereas an acid catalyst in an amount of not more than 10 parts by weight allows easy control of the hydrolysis reaction.

The solvent used in the hydrolysis reaction is not limited to a particular solvent but is appropriately selected in view of, for example, the stability, wetting ability, and volatility of the resin composition. Not only one but also two or more solvents may be used. Specific examples of the solvent can include alcohols such as methanol, ethanol, propanol, isopropanol, butanol, isobutanol, t-butanol, pentanol, 4-methyl-2-pentanol, 3-methyl-2-butanol, 3-methyl-3-methoxy-1-butanol, and diacetone alcohol; glycols such as ethylene glycol and propylene glycol; ethers such as ethylene glycol monomethyl ether, ethylene glycol monoethyl ether, propylene glycol monomethyl ether, propylene glycol monoethyl ether, propylene glycol monopropyl ether, propylene glycol monobutyl ether, propylene glycol mono-t-butyl ether, ethylene glycol dimethyl ether, ethylene glycol diethyl ether, ethylene glycol dibutyl ether, and diethyl ether; ketones such as methyl ethyl ketone, acetylacetone, methyl propyl ketone, methyl butyl ketone, methyl isobutyl ketone, diisobutyl ketone, cyclopentanone, and 2-heptanone; amides such as dimethylformamide and dimethylacetamide; acetates such as ethyl acetate, propyl acetate, butyl acetate, isobutyl acetate, ethylene glycol monoethyl ether acetate, propylene glycol monomethyl ether acetate, 3-methoxybutyl acetate, 3-methyl-3-methoxybutyl acetate, methyl lactate, ethyl lactate, and butyl lactate; aromatic or aliphatic hydrocarbons such as toluene, xylene, hexane, and cyclohexane; and γ-butyrolactone, N-methyl-2-pyrrolidone, and dimethyl sulfoxide.

Among those, for example, propylene glycol monomethyl ether, propylene glycol monomethyl ether acetate, propylene glycol monoethyl ether, propylene glycol monopropyl ether, propylene glycol monobutyl ether, propylene glycol mono-t-butyl ether, and γ-butyrolactone are preferably used in terms of, for example, transmittance and crack resistance of the cured film.

After the completion of the hydrolysis reaction, the resin composition is also preferably adjusted to an appropriate concentration by further adding a solvent thereto. After the hydrolysis, the resin composition may also be heated and/or vacuumed to entirely or partially distil off products such as alcohol and then supplemented with a preferred solvent.

The amount of the solvent used in the hydrolysis reaction is preferably not less than 50 parts by weight and more preferably not less than 80 parts by weight and is also preferably not more than 500 parts by weight and more preferably not more than 200 parts by weight relative to 100 parts by weight of all the alkoxysilane compounds. A solvent amount of not less than 50 parts by weight allows prevention of gel formation. Moreover, a solvent amount of not more than 500 parts by weight allows the hydrolysis reaction to proceed smoothly.

Moreover, the water used in the hydrolysis reaction is preferably ion-exchanged water. The amount of water can be freely selected. However, 1.0 to 4.0 moles of water is preferably used for 1 mole of an alkoxysilane compound(s).

Moreover, the polysiloxane solution after the hydrolysis and the partial condensation preferably contains none of the above-described catalysts from the viewpoint of storage stability of the composition and the catalysts can be removed as necessary. The method of removing the catalysts is not limited to a particular method, but removal by washing with water and/or treatment with ion exchange resins is preferable from the viewpoint of ease of operation and removal performance. The washing with water is a method comprising diluting the polysiloxane solution with an appropriate hydrophobic solvent, washing the resulting solution with water several times, and then concentrating the obtained organic layer by, for example, an evaporator. The treatment with ion exchange resins is a method comprising bringing the polysiloxane solution into contact with appropriate ion exchange resins.

The weight-average molecular weight (Mw) of the polysiloxane (A) is not limited to a particular molecular weight but is preferably not less than 1,000 and more preferably not less than 2,000 and is also preferably not more than 100,000 and further preferably not more than 50,000 in terms of polystyrene as measured by gel permeation chromatography (GPC). The polysiloxane (A) with a Mw within the above-described range provides the resulting resin composition with good coating properties and with good solubility in a developer during pattern formation.

In the resin composition according to an embodiment of the present invention, the content of the polysiloxane (A) is not limited to a particular content but it can be arbitrarily selected depending on a desired film thickness and purposes and, however, is preferably not less than 10% by weight and not less than 80% by weight in the resin composition. Moreover, the content of the polysiloxane (A) is preferably not less than 10% by weight and more preferably not less than 20% by weight and not more than 50% by weight relative to the total amount of solids in the resin composition.

The polysiloxane (A) is preferably obtained by hydrolysis of a mixture containing an organosilane compound having a styryl group and an organosilane compound having a (meth)acryloyl group and an organosilane compound including an organic compound having a hydrophilic group in the presence of metal compound particles as described below and subsequent condensation of the obtained hydrolysis products. This results in increases of refractive index and hardness in the cured film. These increases are understood to result from improvement of the storage stability of the coating liquid and increase of the homogeneity of the cured film due to homogeneous dispersion of the metal compound particles in the polysiloxane, which is caused by polymerization of the polysiloxane in the presence of the metal compound particles and the resulting formation of chemical linkage (covalent linkage) between at least a portion of the polysiloxane and the metal compound particles.

Moreover, the refractive index of the obtained cured film can be adjusted by changing the type of the metal compound particles. As the metal compound particles, metal compound particles as illustrated below may be used.

### <Compound Having a Radical Polymerizable Group and an Aromatic Ring (B)>

The resin composition according to an embodiment of the present invention preferably contains a compound having a radical polymerizable group and an aromatic ring (B) to provide photosensitivity. More specifically, the resin composition preferably comprises the polysiloxane (A) containing styryl group (a-1), (meth)acryloyl group (a-2) and a hydrophilic group (a-3) and further comprises a compound having a radical polymerizable group and an aromatic ring (B).

In this case, it is preferred that the molar contents of styryl groups (a-1) and (meth)acryloyl groups (a-2) in the polysiloxane (A) be, respectively, in the range of not less than 45% by mole to not more than 70% by mole and not less than 15% by mole to not more than 40% by mole relative to 100% by mole of the Si atoms.

Moreover, it is preferred that the hydrophilic group (a-3) be a hydrocarbon group having a structure based on succinic acid or succinic anhydride and the molar content of hydrophilic group (a-3) in the polysiloxane (A) be in the range of not less than 10% by mole to not more than 20% by mole relative to 100% by mole of the Si atoms.

As the compound having a radical polymerizable group and an aromatic ring (B), a divalent (meth)acrylate monomer is preferably used and the divalent (meth)acrylate monomer is preferably represented by the general formula (21) below.

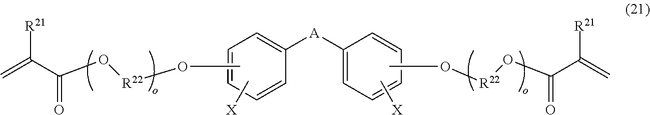

In the general formula (21), R²¹ each independently represents a hydrogen atom or an alkyl group, and R²² each independently represents an alkylene group, and X represents a hydrogen atom or a substituent, and A represents a single bond, —O—, —S—, —R_{d}—, —SO₂—, or a bifunctional group represented by either of the structures as indicated below:

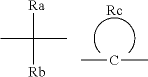

Rₐ and R_{b} each independently represent a hydrogen atom, methyl group, ethyl group, phenyl group, or diphenyl group, and R_{c} represents a C₃₋₂₄ alkylene group, cycloalkylene group, or diphenylene group, and R_{d} represents a C₁₋₁₂ alkylene group or cycloalkylene group, and o each independently represents an integer of 0 to 14.

Preferably, R²¹ each independently represents a hydrogen atom or a methyl group and more preferably a hydrogen atom.

Preferably, R²² each independently represents a C₁₋₁₀ alkylene group and more preferably a C₁₋₄ alkylene group and particularly preferably an ethylene group.

X preferably represents a hydrogen atom. Moreover, X may be, for example, the same as Rₐ and R_{b} below in cases where X is a substituent.

Preferably, Rₐ and R_{b} each independently represent a methyl group or phenyl group and more preferably a methyl group.

R_{c} preferably represents a C₅₋₁₈ alkylene group, C₆₋₁₂ cycloalkylene group, or diphenylene group and more preferably a diphenylene group. The structure containing the functional group R_{c} particularly preferably represents a fluorene group.

R_{d} preferably represents a C₁₋₆ alkylene group or C₁₋₆ cycloalkylene group and more preferably a C₁₋₆ cycloalkylene group.

A preferably represents either of the following structures:

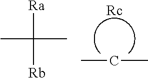

and more preferably represents the following structure:

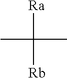

Preferably, the letter o each independently represents an integer of 1 to 10 and more preferably an integer of 1 to 4 and particularly preferably 1.

For example, the following compounds may be used as the compound having a radical polymerizable group and an aromatic ring (B): EO-modified bisphenol A di(meth)acrylate, PO-modified bisphenol A di(meth)acrylate, ECH-modified bisphenol A di(meth)acrylate, EO-modified bisphenol F di(meth)acrylate, ECH-modified hexahydrophthic di(meth)acrylate, ECH-modified phthalic di(meth)acrylate.

Among those, bisphenol A ethoxylate di(meth)acrylate, bisphenol A propioxylate di(meth)acrylate, and bisphenol F ethoxylate di(meth)acrylate, all of which satisfy the above-described general formula (21), are preferably used, and bisphenol A ethoxylate di(meth)acrylate and bisphenol A propioxylate di(meth)acrylate are more preferably used, and bisphenol A ethoxylate di(meth)acrylate is particularly preferably used.

In the resin composition according to an embodiment of the present invention, the content of the compound having a radical polymerizable group and an aromatic ring (B) is not limited to a particular content but is preferably not less than 5% by weight and not more than 35% by weight relative to the total amount of solids in the siloxane resin composition.

### <Photosensitizer (C)>

The resin composition according to an embodiment of the present invention preferably contains a photosensitizer (C) to provide photosensitivity. For example, the presence of a photo-radical polymerization initiator in the resin composition can impart negative photosensitivity to the resulting resin composition. Use of a photo-radical polymerization initiator is preferable from the viewpoint of fine line patterning and hardness.

Any photo-radical polymerization initiator is available as long as it decomposes and/or reacts under light (including ultraviolet light and electron beams) to generate radicals. Specific examples of the photo-radical polymerization initiator include 2-methyl-[4-(methylthio)phenyl]-2-morpholinopropan-1-one, 2-dimethylamino-2-(4-methylbenzyl)-1-(4-morpholin-4-yl-phenyl)-butan-1-one, 2-benzyl-2-dimethylamino-1-(4-morpholinophenyl)-1-butanone, 2,4,6-trimethylbenzoylphenylphosphine oxide, bis(2,4,6-trimethylbenzoyl)-phenylphosphine oxide, bis(2,6-dimethoxybenzoyl)-(2,4,4-trimethylpentyl)-phosphine oxide, 1-phenyl-1,2-propanedione-2-(o-ethoxycarbonyl)oxime, 1-[4-(phenylthio)]-1,2-octanedione 2-(O-benzoyloxime), 1-phenyl-1,2-butanedione-2-(o-methoxycarbonyl)oxime, 1,3-diphenylpropanetrione-2-(o-ethoxycarbonyl)oxime, 1-[9-ethyl-6-(2-methylbenzoyl)-9H-carbazol-3-yl]ethanone 1-(O-acetyloxime), 4,4-bis(dimethylamino)benzophenone, 4,4-bis(diethylamino)benzophenone, ethyl p-dimethylaminobenzoate, 2-ethylhexyl-p-dimethylaminobenzoate, ethyl p-diethylaminobenzoate, diethoxyacetophenone, 2-hydroxy-2-methyl-1-phenylpropan-1-one, benzyldimethylketal, 1-(4-isopropylphenyl)-2-hydroxy-2-methylpropan-1-one, 4-(2-hydroxyethoxy)phenyl-(2-hydroxy-2-propyl) ketone, 1-hydroxycyclohexyl-phenyl ketone, benzoin, benzoin methyl ether, benzoin ethyl ether, benzoin isopropyl ether, benzoin isobutyl ether, benzophenone, methyl o-benzoylbenzoate, 4-phenylbenzophenone, 4,4-dichlorobenzophenone, hydroxybenzophenone, 4-benzoyl-4′-methyl-diphenyl sulfide, alkylationbenzophenone, 3,3′,4,4′-tetra(t-butylperoxycarbonyl)benzophenone, 4-benzoyl-N,N-dimethyl-N-[2-(1-oxo-2-propenyloxy)ethyl]benzenemethanaminium bromide, (4-benzoylbenzyl)trimethylammonium chloride, 2-hydroxy-3-(4-benzoylphenoxy)-N,N,N-trimethyl-1-propenaminium chloride monohydrate, 2-isopropylthioxanthone, 2,4-dimethylthioxanthone, 2,4-diethylthioxanthone, 2,4-dichlorothioxanthone, 2-hydroxy-3-(3,4-dimethyl-9-oxo-9H-thioxanthen-2-yloxy)-N,N,N-trimethyl-1-propanaminium chloride, 2,2′-bis(o-chlorophenyl)-4,5,4′,5′-tetraphenyl-1,2-biimidazole, 10-butyl-2-chloroacridone, 2-ethylanthraquinone, benzyl, 9,10-phenanthrenequinone, camphorquinone, methyl phenyl glyoxylate, η5-cyclopentadienyl-η6-cumenyl-iron(1+)-hexafluorophosphate(1−), diphenyl sulfide derivatives, bis(η5-2,4-cyclopentadien-1-yl)-bis(2,6-difluoro-3-(1H-pyrrol-1-yl)-phenyl) titanium, thioxanthone, 2-methylthioxanthone, 2-chlorothioxanthone, 4-benzoyl-4-methylphenyl ketone, dibenzyl ketone, fluorenone, 2,3-diethoxyacetophenone, 2,2-dimethoxy-2-phenyl-2-phenylacetophenone, 2-hydroxy-2-methylpropiophenone, p-t-butyldichloroacetophenone, benzyl methoxyethyl acetal, anthraquinone, 2-t-butylanthraquinone, 2-aminoanthraquinone, β-chloroanthraquinone, anthrone, benzanthrone, dibenzosuberone, methyleneanthrone, 4-azidebenzalacetophenone, 2,6-bis(p-azidebenzylidene)cyclohexane, 2,6-bis(p-azidebenzylidene)-4-methylcyclohexanone, naphthalenesulfonyl chloride, quinolinesulfonyl chloride, N-phenylthioacridone, benzothiazole disulfide, triphenylphosphine, carbon tetrabromide, tribromophenyl sulfone, benzoyl peroxide and combinations of photoreducing dyes such as eosin and methylene blue and reducing agents such as ascorbic acid and triethanolamine. Two or more of them may be contained.

Among those, α-aminoalkylphenone compounds, acylphosphine oxide compounds, oxime ester compounds, amino group-containing benzophenone compounds or amino group-containing benzoate compounds are preferable from the viewpoint of patterning properties and hardness of the cured film. Each of the compounds is also involved as a base or an acid in cross-linking of siloxanes upon light exposure and thermal curing to further increase the hardness of the cured film.

Specific examples of the a-aminoalkylphenone compounds include 2-methyl-[4-(methylthio)phenyl]-2-morpholinopropan-1-one, 2-dimethylamino-2-(4-methylbenzyl)-1-(4-morpholin-4-yl-phenyl)-butan-1-one, and 2-benzyl-2-dimethylamino-1-(4-morpholinophenyl)-1-butanone.

Specific examples of the acylphosphine oxide compounds include 2,4,6-trimethylbenzoylphenylphosphine oxide, bis(2,4,6-trimethylbenzoyl)-phenylphosphine oxide, and bis(2,6-dimethoxybenzoyl)-(2,4,4-trimethylpentyl)-phosphine oxide.

Specific examples of the oxime ester compounds include 1-phenyl-1,2-propanedione-2-(o-ethoxycarbonyl)oxime, 1-[4-(phenylthio)]-1,2-octanedione 2-(O-benzoyloxime), 1-phenyl-1,2-butanedione-2-(o-methoxycarbonyl)oxime, 1,3-diphenylpropanetrione-2-(o-ethoxycarbonyl)oxime, and 1-[9-ethyl-6-(2-methylbenzoyl)-9H-carbazol-3-yl]ethanone 1-(O-acetyloxime).

Specific examples of the amino group-containing benzophenone compounds include 4,4-bis(dimethylamino)benzophenone and 4,4-bis(diethylamino)benzophenone.

Specific examples of the amino group-containing benzoate compounds include ethyl p-dimethylaminobenzoate, 2-ethylhexyl-p-dimethylaminobenzoate, and ethyl p-diethylaminobenzoate.

Among those, the photopolymerization initiators containing a sulfur atom are more preferable from the viewpoint of patterning properties. Specific examples of the photopolymerization initiators containing a sulfur atom include 2-methyl-[4-(methylthio)phenyl]-2-morpholinopropan-1-one and 1-[4-(phenylthio)]-1,2-octanedione 2-(O-benzoyloxime).

In the resin composition according to an embodiment of the present invention, the content of the photosensitizer (C) is not limited to a particular content but is preferably not less than 0.01% by weight, more preferably not less than 0.1% by weight, and further preferably not less than 1% by weight and is also preferably not more than 20% by weight and more preferably not more than 10% by weight relative to the total amount of solids in the resin composition. The content of the photosensitizer within the above-described range allows radical curing to proceed sufficiently and prevents the residual radical polymerization initiator from, for example, leaking out of the resulting cured film and then successfully ensures solvent resistance in the cured film.

### <Metal Compound Particle (D)>

Preferably, the resin composition according to an embodiment of the present invention further contains metal compound particles (D). The metal compound particles (D) may be one or more types of metal compound particles selected from aluminium compound particles, tin compound particles, titanium compound particles and zirconium compound particles, or composite particles of a silicon compound and one or more types of metal compounds selected from aluminium compounds, tin compounds, titanium compounds and zirconium compounds.

Among those, any one or more selected from titanium compound particles such as titanium oxide particles and zirconium compound particles such as zirconium oxide particles are preferable from the viewpoint of increasing the refractive index. The refractive index can be adjusted to a desired range by including any one or more selected from titanium oxide particles and zirconium oxide particles in the resin composition. Moreover, the presence of those particles can further increase the hardness, scratch resistance, and crack resistance of the cured film.

The number-average particle diameter of the metal compound particles (D) is preferably from 1 nm to 200 nm. The metal compound particles with a number-average particle diameter of 1 nm or more, more preferably of 5 nm or more, can prevent cracks from occurring during the formation of a thick film. Moreover, the metal compound particles with a number-average particle diameter of 200 nm or less, more preferably of 70 nm or less, can increase the transparency of the cured film to visible light.

As used herein, the number-average particle diameter of the metal compound particles (D) refers to a value measured by the dynamic light scattering technique. The instrument to be used is not limited to a particular instrument but can include the DLS-8000 dynamic light scattering altimeter (manufactured by Otsuka Electronics Co., Ltd.).

In the resin composition according to an embodiment of the present invention, the content of the metal compound particles (D) is preferably not less than 10 parts by weight and not more than 500 parts by weight and more preferably not less than 100 parts by weight and not more than 400 parts by weight relative to 100 parts by weight of the total amount of organosilane compounds that constitute the polysiloxane (A). The metal compound particles in an amount of not less than 10 parts by weight further increase the refractive index under the influence of the high refractive index of the metal compound particles. The metal compound particles in an amount of not more than 500 parts by weight further increase the chemical resistance by filling the space between particles with other composition.

Moreover, the content of the metal compound particles (D) is preferably not less than 30% by weight and not more than 60% by weight and more preferably not less than 40% by weight and not more than 60% by weight, which are, respectively, the lower and upper limits, relative to all the solids in the photosensitive resin composition. The metal compound particles in an amount within the above-described range can provide a cured film with a high refractive index.

Examples of the metal compound particles (D) include the tin oxide-titanium oxide composite particles “OPTOLAKE TR-502” and “OPTOLAKE TR-504,” the silicon oxide-titanium oxide composite particles “OPTOLAKE TR-503,” “OPTOLAKE TR-513,” “OPTOLAKE TR-520,” “OPTOLAKE TR-527,” “OPTOLAKE TR-528,” “OPTOLAKE TR-529,” “OPTOLAKE TR-543,” “OPTOLAKE TR-544,” and “OPTOLAKE TR-550,” the titanium oxide particles “OPTOLAKE TR-505” (tradenames; manufactured by JGC C&C), NOD-7771GTB (tradename; manufactured by Nagase ChemteX Co.), zirconium oxide particles (manufactured by Kojundo Chemical Lab. Co., Ltd.), tin oxide-zirconium oxide composite particles (manufactured by JGC C&C), tin oxide particles (manufactured by Kojundo Chemical Lab. Co., Ltd.), “Bayral” Zr-C20 (titanium oxide particles; mean particle size=20 nm; manufactured by Taki Chemical Co., Ltd.), ZSL-10A (titanium oxide particles; mean particle size=60-100 nm; manufactured by Daiichi Kigenso Kagaku Kogyo Co., Ltd.), NanoUse OZ-30M (titanium oxide particles; mean particle size=7 nm; manufactured by Nissan Chemical Co.), SZR-M or SZR-K (zirconium oxide particles; manufactured by Sakai Chemical Industry Co., Ltd.), HXU-120JC (zirconium oxide particles; manufactured by Sumitomo Osaka Cement Co., Ltd.), ZR-010 (zirconium oxide particles; Solar Co., Ltd), or ZRPMA (zirconia particles; C. I. Kasei Co., Ltd.).

### <Solvent (E)>

The resin composition according to an embodiment of the present invention may contain a solvent (E). The solvent is preferably used to adjust the concentration of the resin composition so that the film thickness X or X′ ranges from 0.95 to 1.1 μm.

Specific examples of the solvent (E) include ethers such as ethylene glycol monomethyl ether, ethylene glycol monoethyl ether, propylene glycol monomethyl ether, propylene glycol monoethyl ether, propylene glycol monopropyl ether, propylene glycol monobutyl ether, propylene glycol mono-t-butyl ether, ethylene glycol dimethyl ether, ethylene glycol diethyl ether, and ethylene glycol dibutyl ether; acetates such as ethylene glycol monoethyl ether acetate, propylene glycol monomethyl ether acetate, propyl acetate, butyl acetate, isobutyl acetate, 3-methoxybutyl acetate, 3-methyl-3-methoxybutyl acetate, methyl lactate, ethyl lactate, and butyl lactate; ketones such as acetylacetone, methyl propyl ketone, methyl butyl ketone, methyl isobutyl ketone, cyclopentanone, and 2-heptanone; alcohols such as methanol, ethanol, propanol, butanol, isobutyl alcohol, pentanol, 4-methyl-2-pentanol, 3-methyl-2-butanol, 3-methyl-3-methoxy-1-butanol, and diacetone alcohol; aromatic hydrocarbons such as toluene and xylene; and γ-butyrolactone, and N-methylpyrrolidinone. These solvents may be used singly or in combination.

Among those, particularly preferably examples of the solvent are, for example, propylene glycol monomethyl ether, propylene glycol monomethyl ether acetate, propylene glycol monoethyl ether, propylene glycol monopropyl ether, propylene glycol monobutyl ether, propylene glycol mono-t-butyl ether, diacetone alcohol, and γ-butyrolactone. Those solvents may be used singly or in combination of two or more.

The total content of solvents in the resin composition according to an embodiment of the present invention is preferably in the range of 100 parts by weight to 9900 parts by weight and more preferably in the range of 100 parts by weight to 5000 parts by weight relative to 100 parts by weight of all the alkoxysilane compounds.

### <Other Ingredients>

The resin composition according to an embodiment of the present invention may contain a cross-linking agent or a curing agent to promote or facilitate curing of the resin composition. Specific examples of such agents include silicone resin-based curing agents, various metal alcoholates, various metal chelate compounds, isocyanate compounds, and polymers thereof. One or more of them may be contained.

The resin composition according to an embodiment of the present invention may contain a various type of surfactant for the purpose of increasing the flowability during coating and the uniformity in film thickness. The type of the surfactant is not limited to a particular type but, for example, fluorine-based surfactants, silicone-based surfactants, polyalkyleneoxide-based surfactants, and poly(meth)acrylate-based surfactants can be used. Among those, fluorine-based surfactants are particularly preferably used from the viewpoint of flowability and uniformity in film thickness.

Specific examples of the fluorine-based surfactants can include fluorine-based surfactants consisting of compounds that contain a fluoroalkyl group(s) or a fluoroalkylene group(s) in at least any of the termini, the main chain and the side chain, such as 1,1,2,2-tetrafluorooctyl(1,1,2,2-tetrafluoropropyl)ether, 1,1,2,2-tetrafluorooctyl hexyl ether, octaethylene glycol di(1,1,2,2-tetrafluorobutyl)ether, hexaethylene glycol (1,1,2,2,3,3-hexafluoropentyl)ether, octapropylene glycol di(1,1,2,2-tetrafluorobutyl)ether, hexapropylene glycol di(1,1,2,2,3,3-hexafluoropentyl)ether, sodium perfluorododecylsulfonate, 1,1,2,2,8,8,9,9,10,10-decafluorododecane, 1,1,2,2,3,3-hexafluorodecane, N-[3-(perfluorooctanesulfonamido)propyl]-N,N′-dimethyl-N-carboxymethylene ammonium betaine, (perfluoroalkylsulfonamido)propyl trimethylammonium, perfluoroalkyl-N-ethyl sulfonylglycine, bis(N-perfluorooctylsulfonyl-N-ethylaminoethyl) phosphate, and monoperfluoroalkyl ethyl phosphate.

Moreover, commercially available products of the fluorine-based surfactants can include “Megafac” (registered trademark) F142D, F172, F173, and F183 (manufactured by Dainippon Ink & Chemicals, Inc.), “F-Top” (registered trademark) EF301, 303, and 352 (manufactured by New Akita Chemicals Co.), “Fluorad” FC-430 and FC-431 (manufactured by Sumitomo 3M Ltd.), “Asahi Guard” (registered trademark) AG710, “Surflon” (registered trademark) S-382, SC-101, SC-102, SC-103, SC-104, SC-105, and SC-106 (manufactured by Asahi Glass Co., Ltd.), “BM-1000” and “BM-1100” (manufactured by Yusho Co., Ltd.), “NBX-15” and “FTX-218” (manufactured by Neos Co., Ltd.). Among those, the above-described “Megafac” (registered trademark) F172, “BM-1000,” “BM-1100,” “NBX-15,” and “FTX-218” are particularly preferably from the viewpoint of flowability and uniformity in film thickness.

Commercially available products of the silicone-based surfactants include “SH28PA,” “SH7PA,” “SH21PA,” “SH30PA,” and “ST94PA” (manufactured by Dow Corning Toray Silicone Co., Ltd.), and “BYK-333” (manufactured by BYK Japan KK). Examples of other surfactants include polyoxyethylene lauryl ether, polyoxyethylene stearyl ether, polyoxyethylene nonylphenyl ether, and polyoxyethylene distearate.

The content of the surfactant in the resin composition according to an embodiment of the present invention is normally in the range of 0.001 to 10 parts by weight relative to 100 parts by weight of all the alkoxysilane compounds in the resin composition. One or more of them may be simultaneously used.

The resin composition according to an embodiment of the present invention may contain, for example, a viscosity modifier, a stabilizer, a coloring agent, and a glass forming agent, as necessary.

A preferred exemplary composition of the resin composition according to an embodiment of the present invention, particularly a composition to impart photosensitivity to the resin composition, is indicated below. The resin composition contains:

the polysiloxane (A) in a ratio of not less than 20% by weight and not more than 50% by weight,
the compound having a radical polymerizable group and an aromatic ring (B) in a ratio of not less than 5% by weight and not more than 35% by weight,
the photosensitizer (C) in a ratio of not less than 1% by weight and not more than 10% by weight, and
the metal compound particles (D) in a ratio of not less than 30% by weight and not more than 60% by weight.

### <Production Method for a Cured Film>

A production method for a cured film according to an embodiment of the present invention preferably comprises the steps of:

(I) applying the above-described resin composition on a substrate to prepare a coated film; and
(III) curing the coated film by heating.

Moreover, the following step is preferably further introduced between the steps (I) and (III) in cases where the above-described resin composition is a photosensitive resin composition:

(II) the step of exposing the coated film to light and developing the exposed film. The method is described below by way of examples.

### (I) Step of Applying the Resin Composition on a Substrate to Prepare a Coated Film

The above-described resin composition is applied on a substrate by a known technique such as spin coating or slit coating and then heated (pre-baked) with a heating apparatus such as hot plate or oven. The pre-baking is preferably performed at a temperature within the range of 50 to 150° C. for 30 seconds to 30 minutes. The thickness of the pre-baked film is preferably from 0.1 to 15 μm.

### (II) Step of Exposing the Coated Film to Light and Developing the Exposed Film

After pre-baking, the coated film is exposed to light for pattern formation through a desired mask at an exposure dose of about 10 to 4000 J/m² (in terms of exposure dose at a wavelength of 365 nm) by using a ultraviolet-visible exposure machine such as stepper, mirror projection mask aligner (MPA), or parallel light mask aligner (PLA).

After exposure to light, the unexposed portion of the film is dissolved and removed by developing the film to obtain a negative pattern. The pattern resolution is preferably 15 μm or less. The developing technique includes techniques based on, for example, a showering, dipping, or paddling mechanism and the developing technique preferably comprises immersing the film in a developer for 5 seconds to 10 minutes. A known alkaline developer may be used as the developer and examples of the developer include aqueous solution of the following alkaline components: inorganic alkaline components such as hydroxides, carbonates, phosphates, silicates, and borates of alkali metals; amines such as 2-diethylaminoethanol, monoethanolamine, and diethanolamine; and quaternary ammonium salts such as tetramethylammonium hydroxide (TMAH) and choline. Two or more of them may be used as the alkaline developer.

Moreover, the film is preferably rinsed in water after film development and may be dried as necessary by baking at a temperature within the range of 50 to 150° C. on a heating apparatus such as hot plate or oven. The film is further heated (soft-baked) as necessary at a temperature within the range of 50 to 300° C. for 30 seconds to 30 minutes on a heating apparatus such as hot plate or oven.

### (III) Step of Curing the Coated Film by Heating

The coated film obtained from the step (I), or the coated film obtained from the steps (I) and (II) is heated (cured) at a temperature within the range of 150 to 450° C. for about 30 seconds to 2 hours on a heating apparatus such as hot plate or oven to obtain a cured film.

The resin composition according to an embodiment of the present invention is preferably sensitive to exposure to light at a dose of 1500 J/m² or less and more preferably of 1000 J/m² or less in the exposure and development step (II), from the viewpoint of productivity during pattern formation. Such high sensitivity can be achieved by a photosensitive resin composition that contains a polysiloxane produced by using an organosilane compound(s) containing styryl groups and/or (meth)acryloyl groups.

The sensitivity of the resin composition upon light exposure is measured by the following procedure. The photosensitive resin composition is applied on a silicon wafer by spin coating using a spin coater at an arbitrary rotational speed. The coated film is pre-baked at 120° C. for 3 minutes by using a hot plate to prepare a pre-baked film with a film thickness of 1 μm. The pre-baked film is exposed to light from an ultrahigh pressure mercury lamp through a mask for sensitivity measurement, which is a gray scale mask having a line-and-space pattern with a pitch of 1 to 10 μm, by using a PLA mask aligner (PLA-501F; manufactured by Canon Inc.). Subsequently, the film is developed in a shower of 2.38% by weight TMAH in water for 90 seconds by using an automatic developing machine (AD-2000; manufactured by Takizawa Sangyo Co., Ltd.) and then rinsed in water for 30 seconds. Among exposure doses which allow a square pattern with a designed dimension of 100 μm×100 μm in the formed pattern to remain on the substrate without being stripped therefrom after the development, the lowest exposure dose (hereinafter referred to as optimal exposure dose) is considered as the sensitivity of the resin composition.

Subsequently, the developed film is cured at 220° C. for 5 minutes by using a hot plate in the thermal curing step to prepare a cured film and the post-cure resolution is identified as the smallest pattern dimension on the resulting cured film at the above sensitivity.

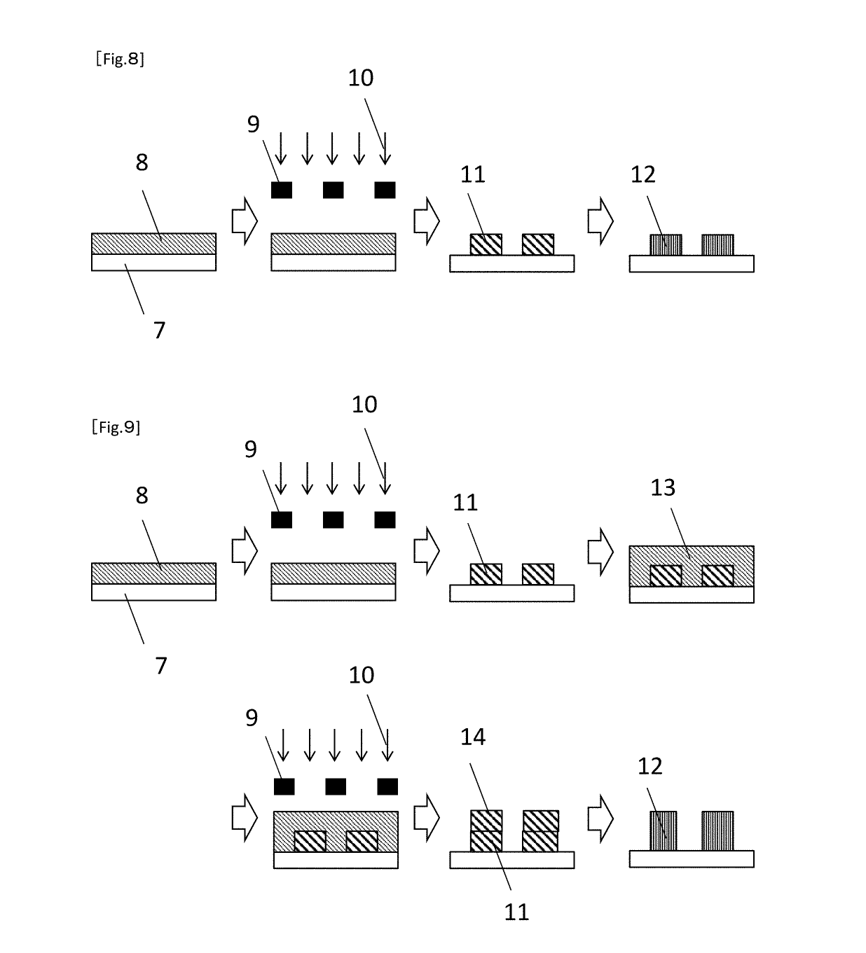

FIG. 8 shows a specific example of the production of a cured film according to an embodiment of the present invention. First, the above-described resin composition is applied on a substrate 7 to prepare a coated film 8. Then, the coated film 8 is exposed to light through a mask 9 by irradiation with activating light 10. Then, the film is developed to give a pattern 11 and is further heated to give a cured film 12.

Moreover, a second production method for a cured film according to an embodiment of the present invention preferably comprises the steps of:

(I) applying the above-described resin composition on a substrate to prepare a coated film;
(II) exposing the coated film to light and developing the exposed film;
(IV) further applying the above-described resin composition on the above-described developed coated film to prepare a second coated film;
(V) exposing the above-described second coated film to light and developing the exposed film; and
(VI) heating the above-described developed coated film and the above-described developed second coated film.

In this example, the steps (I) and (II) are performed according to the same procedure as described above. Moreover, the steps (IV) to (VI) can be performed according to the same procedure as described for the steps (I) to (III), respectively.

The first coated film obtained from the steps (I) and (II) preferably has the same pattern as that on the second coated film obtained from the steps (IV) and (V). This allows providing a two-level pattern. Moreover, the pattern on each level can be simultaneously cured according to the step (VI).

FIG. 9 shows a specific example of the production of a cured film according to this production method. The above-described procedure is performed until the pattern 11 is prepared on the first coated film. Then, the above-described photosensitive resin composition is applied on the pattern 11 to prepare a second coated film 13. The same mask 9 as used in the exposure of the first coated film to light is used and the activating light 10 is irradiated. This allows providing a pattern 14 on the pattern 11. These patterns are heated to provide a cured film 12 which has a film thickness corresponding to the two layers of film.

Moreover, a third production method for a cured film according to an embodiment of the present invention preferably comprises the steps of:

(I) applying the above-described resin composition on a substrate to prepare a coated film;
(II) exposing the coated film to light and developing the exposed film;
(III) heating the developed coated film;
(IV′) further applying the above-described resin composition on the aforementioned heated coated film to prepare a second coated film;
(V′) exposing the second coated film to light and developing the exposed film; and
(VI′) heating the developed second coated film.

In this embodiment, the steps (I) to (III) are performed according to the same procedure as described above. Moreover, the steps (IV′) to (VI′) can be performed according to the same procedure as described for the steps (IV) to (VI), respectively.

The first pattern obtained from the steps (I) to (III) is preferably the same as the second pattern obtained from the steps (IV) to (VI). This allows providing a two-level pattern.

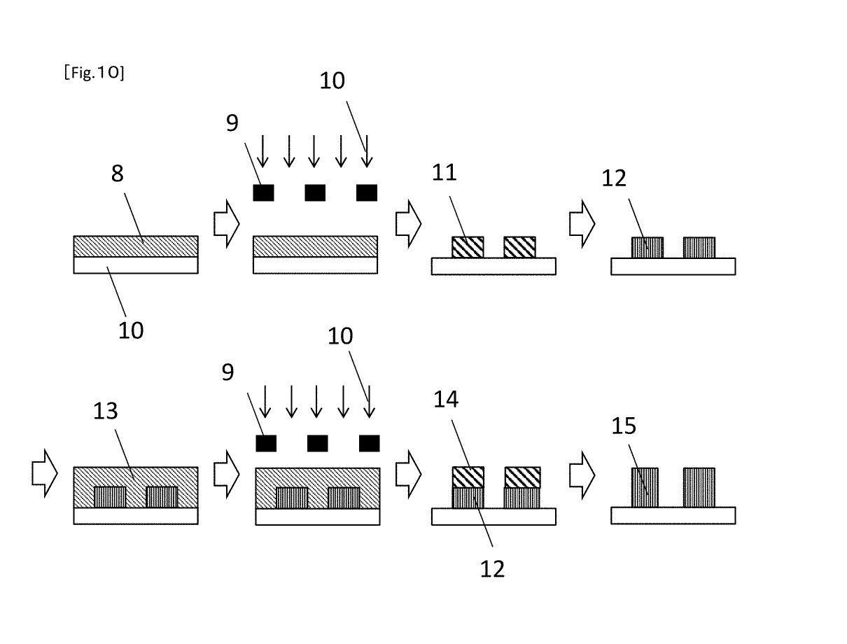

FIG. 10 shows a specific example of the production of a cured film according to the third production method. The above-described procedure is performed until the first cured film 12 is prepared. Then, the above-described resin composition is applied on the cured film 12 to prepare a second coated film 13. The same mask 9 as used in the exposure of the first coated film to light is used and the activating light 10 is irradiated. This allows providing a pattern 14 on the pattern in the cured film 12. This is heated to provide a cured film 15 which has a film thickness corresponding to the two layers of film.

The resin composition according to the present invention and a cured film of the resin composition are suitably used in optical devices such as solid-state image sensors, optical filters, and displays. More specific examples of the optical devices include light condenser microlenses and optical waveguides formed in, for example, solid-state image sensors such as backside illumination CMOS image sensors; anti-reflection films provided as optical filters; planarization materials for TFT substrates for use in displays; color filters and protection films for liquid crystalline displays and the like; and phase shifters. The resin composition and the cured film can achieve both high transparency and high refractive index and are thus particularly suitably used in a light condenser microlens formed on a solid-state image sensor or an optical waveguide linking a light condenser microlens to an optical sensor, among others. Moreover, the resin composition and the cured film can also be used in a buffer coat, an interlayer dielectric film and various protection films in a semiconductor device. The photosensitive resin composition according to the present invention eliminates the need for pattern formation by etching and thus enables to simplify the process associated with pattern formation and to avoid the degradation of wiring due to an etching solution or plasma.

### EXAMPLES

The present invention will be further specifically described below by way of examples. However, the present invention is not limited to these examples. Abbreviations for compounds used in Synthesis Example and Example are indicated below.

### <Alkoxysilane Compounds>

MTMS: methyltrimethoxysilane
MTES: methyltriethoxysilane
PhTMS: phenyltrimethoxysilane
PhTES: phenyltriethoxysilane
StTMS: styryltrimethoxysilane
StTES: styryltriethoxysilane
SuTMS: [3-(trimethoxysilyl)propyl]succinic anhydride
EpCTMS: 2-(3,4-epoxycyclohexyl)ethyltrimethoxysilane
NaTMS: 1-naphthyltrimethoxysilane
AcTMS: γ-acryloxypropyltrimethoxysilane
MAcTMS: γ-methacryloxypropyltrimethoxysilane
DPD: diphenylsilanediol
TIP: tetraisopropoxytitanium

### <Solvents>

PGMEA: propylene glycol monomethyl ether acetate
PGME: propylene glycol monomethyl ether
DAA: diacetone alcohol
THF: tetrahydrofurane

### NMP: N-methylpyrrolidone

### <Concentration of Solids>

The concentration of solids in a polysiloxane solution was measured by the following procedure. A polysiloxane solution weighing 1.5 g was placed in an aluminium cup and was heated at 250° C. for 30 minutes by using a hot plate to evaporate water. The solids remaining in the aluminium cup after heating was weighed to obtain the concentration of solids in the polysiloxane solution.

### <Determination of the Ratio of Styryl Groups>

The ²⁹Si-NMR spectra were measured and the integrated value for each organosilane was compared with the total integrated value for all the components to calculate the ratio. A sample (liquid) was injected into an NMR sample tube made of “Teflon” (registered trademark) and having a diameter of 10 mm and used for the measurement. The conditions for the measurement of ²⁹Si-NMR spectra are presented below.

Instrument: JNM GX-270 manufactured by JEOL Ltd.

Measurement method: the gated decoupling technique Measurement nuclear frequency: 53.6693 MHz (²⁹Si nuclide)

Spectrum width: 20000 Hz

Pulse width: 12 μsec (45 degree)

Pulse recurrence time: 30.0 sec

Solvent: acetone-d6

Reference substance: tetramethylsilane

Measurement temperature: room temperature

Sample rotational speed: 0.0 Hz

### Polymer Synthesis in Examples

### Synthesis Example 1. Synthesis of Polysiloxane (P-1)

Into a 500-mL three-neck flask, 27.24 g (0.2 mol) of MTMS, 56.08 g (0.25 mol) of StTMS, 12.32 g (0.05 mol) of EpCTMS, and 113.54 g of PGME were introduced, and the resulting mixture was stirred at room temperature while a mixture of 27.0 g of water and 0.478 g of phosphoric acid was added thereto over 30 minutes. Subsequently, the resulting mixture was stirred for 1 hour while the flask was heated in an oil bath at 70° C., and the temperature of the oil bath was then increased to 110° C. over 30 minutes. The internal temperature of the solution reached 100° C. at one hour after starting the temperature rise, and the solution was stirred for further 2 hours with heating (the internal temperature was from 100 to 110° C.). The by-products, methanol and water, in a total of 62 g were distilled off during the reaction. The solution of the resulting polysiloxane in PGME which remained in the flask was named the PGME solution of the polysiloxane (P-1). The concentration of solids in this solution was 35.2%. The molar content of styryl groups in the polysiloxane (P-1) measured by ²⁹Si-NMR was 50% by mole.

### Synthesis Example 2. Synthesis of Polysiloxane (P-2)

According to the same procedure as in Synthesis Example 1, 39.66 g (0.2 mol) of PhTMS, 56.08 g (0.25 mol) of StTMS, 12.32 g (0.05 mol) of EpCTMS, and 136.6 g of PGME were introduced into a flask, and a mixture of 27.0 g of water and 0.54 g of phosphoric acid was added thereto to synthesize a polysiloxane (P-2). The concentration of solids in the PGME solution of the polysiloxane (P-2) was 34.9%. The molar content of styryl groups in the polysiloxane (P-2) measured by ²⁹Si-NMR was 50% by mole.

### Synthesis Example 3. Synthesis of Polysiloxane (P-3)

According to the same procedure as in Synthesis Example 1, 49.67 g (0.2 mol) of NaTMS, 56.08 g (0.25 mol) of StTMS, 12.32 g (0.05 mol) of EpCTMS, and 155.19 g of PGME were introduced into a flask, and a mixture of 27.0 g of water and 0.59 g of phosphoric acid was added thereto to synthesize a polysiloxane (P-3). The concentration of solids in the PGME solution of the polysiloxane (P-3) was 34.7%. The molar content of styryl groups in the polysiloxane (P-3) measured by ²⁹Si-NMR was 50% by mole.

### Synthesis Example 4. Synthesis of Polysiloxane (P-4)

According to the same procedure as in Synthesis Example 1, 46.86 g (0.2 mol) of AcTMS, 56.08 g (0.25 mol) of StTMS, 12.32 g (0.05 mol) of EpCTMS, and 149.97 g of PGME were introduced into a flask, and a mixture of 27.0 g of water and 0.576 g of phosphoric acid was added thereto to synthesize a polysiloxane (P-4). The concentration of solids in the PGME solution of the polysiloxane (P-4) was 35.2%. The molar content of styryl groups in the polysiloxane (P-4) measured by ²⁹Si-NMR was 50% by mole.

### Synthesis Example 5. Synthesis of Polysiloxane (P-5)

According to the same procedure as in Synthesis Example 1, 49.68 g (0.2 mol) of MAcTMS, 56.08 g (0.25 mol) of StTMS, 12.32 g (0.05 mol) of EpCTMS, and 155.21 g of PGME were introduced into a flask, and a mixture of 27.0 g of water and 0.59 g of phosphoric acid was added thereto to synthesize a polysiloxane (P-5).

The concentration of solids in the PGME solution of the polysiloxane (P-5) was 35.0%. The molar content of styryl groups in the polysiloxane (P-5) measured by ²⁹Si-NMR was 50% by mole.

### Synthesis Example 6. Synthesis of Polysiloxane (P-6)

According to the same procedure as in Synthesis Example 1, 49.67 g (0.2 mol) of NaTMS, 56.08 g (0.25 mol) of StTMS, 13.12 g (0.05 mol) of SuTMS, and 158.34 g of PGME were introduced into a flask, and a mixture of 27.9 g of water and 0.594 g of phosphoric acid was added thereto to synthesize a polysiloxane (P-6). The concentration of solids in the PGME solution of the polysiloxane (P-6) was 35.4%. The molar content of styryl groups in the polysiloxane (P-6) measured by ²⁹Si-NMR was 50% by mole.

### Synthesis Example 7. Synthesis of Polysiloxane (P-7)

According to the same procedure as in Synthesis Example 1, 46.86 g (0.2 mol) of AcTMS, 56.08 g (0.25 mol) of StTMS, 13.12 g (0.05 mol) of SuTMS, and 153.12 g of PGME were introduced into a flask, and a mixture of 27.9 g of water and 0.58 g of phosphoric acid was added thereto to synthesize a polysiloxane (P-7). The concentration of solids in the PGME solution of the polysiloxane (P-7) was 35.6%. The molar content of styryl groups in the polysiloxane (P-7) measured by ²⁹Si-NMR was 50% by mole.

### Synthesis Example 8. Synthesis of Polysiloxane (P-8)

According to the same procedure as in Synthesis Example 1, 49.68 g (0.2 mol) of MAcTMS, 56.08 g (0.25 mol) of StTMS, 13.12 g (0.05 mol) of SuTMS, and 158.36 g of PGME were introduced into a flask, and a mixture of 27.9 g of water and 0.594 g of phosphoric acid was added thereto to synthesize a polysiloxane (P-8).

The concentration of solids in the PGME solution of the polysiloxane (P-8) was 35.3%. The molar content of styryl groups in the polysiloxane (P-8) measured by ²⁹Si-NMR was 50% by mole.

### Synthesis Example 9. Synthesis of Polysiloxane (P-9)

According to the same procedure as in Synthesis Example 1, 58.58 g (0.25 mol) of AcTMS, 44.86 g (0.2 mol) of StTMS, 13.12 g (0.05 mol) of SuTMS, and 154.05 g of PGME were introduced into a flask, and a mixture of 27.9 g of water and 0.583 g of phosphoric acid was added thereto to synthesize a polysiloxane (P-9). The concentration of solids in the PGME solution of the polysiloxane (P-9) was 35.1%. The molar content of styryl groups in the polysiloxane (P-9) measured by ²⁹Si-NMR was 40% by mole.

### Synthesis Example 10. Synthesis of Polysiloxane (P-10)

According to the same procedure as in Synthesis Example 1, 35.15 g (0.15 mol) of AcTMS, 67.29 g (0.3 mol) of StTMS, 13.12 g (0.05 mol) of SuTMS, and 152.20 g of PGME were introduced into a flask, and a mixture of 27.9 g of water and 0.578 g of phosphoric acid was added thereto to synthesize a polysiloxane (P-10). The concentration of solids in the PGME solution of the polysiloxane (P-10) was 35.5%. The molar content of styryl groups in the polysiloxane (P-10) measured by ²⁹Si-NMR was 60% by mole.

### Synthesis Example 11. Synthesis of Polysiloxane (P-11)

According to the same procedure as in Synthesis Example 1, 23.43 g (0.1 mol) of AcTMS, 78.51 g (0.35 mol) of StTMS, 13.12 g (0.05 mol) of SuTMS, and 151.27 g of PGME were introduced into a flask, and a mixture of 27.9 g of water and 0.575 g of phosphoric acid was added thereto to synthesize a polysiloxane (P-11). The concentration of solids in the PGME solution of the polysiloxane (P-11) was 35.5%. The molar content of styryl groups in the polysiloxane (P-11) measured by ²⁹Si-NMR was 70% by mole.

### Synthesis Example 12. Synthesis of Polysiloxane (P-12)

According to the same procedure as in Synthesis Example 1, 11.72 g (0.05 mol) of AcTMS, 89.72 g (0.4 mol) of StTMS, 13.12 g (0.05 mol) of SuTMS, and 150.34 g of PGME were introduced into a flask, and a mixture of 27.9 g of water and 0.573 g of phosphoric acid was added thereto to synthesize a polysiloxane (P-12). The concentration of solids in the PGME solution of the polysiloxane (P-12) was 35.3%. The molar content of styryl groups in the polysiloxane (P-12) measured by ²⁹Si-NMR was 80% by mole.

### Synthesis Example 13. Synthesis of Polysiloxane (P-13)

According to the same procedure as in Synthesis Example 1, 30.65 g (0.225 mol) of MTMS, 56.08 g (0.25 mol) of StTMS, 13.12 g (0.025 mol) of SuTMS, and 110 g of PGME were introduced into a flask, and a mixture of 27.45 g of water and 0.466 g of phosphoric acid was added thereto to synthesize a polysiloxane (P-13). The concentration of solids in the PGME solution of the polysiloxane (P-13) was 35.1%. The molar content of styryl groups in the polysiloxane (P-13) measured by ²⁹Si-NMR was 50% by mole.

### Synthesis Example 14. Synthesis of Polysiloxane (P-14)

According to the same procedure as in Synthesis Example 1, 23.84 g (0.175 mol) of MTMS, 56.08 g (0.25 mol) of StTMS, 19.67 g (0.075 mol) of SuTMS, and 123.39 g of PGME were introduced into a flask, and a mixture of 28.35 g of water and 0.498 g of phosphoric acid was added thereto to synthesize a polysiloxane (P-14). The concentration of solids in the PGME solution of the polysiloxane (P-14) was 35.4%. The molar content of styryl groups in the polysiloxane (P-14) measured by ²⁹Si-NMR was 50% by mole.

### Synthesis Example 15. Synthesis of Polysiloxane (P-15)

According to the same procedure as in Synthesis Example 1, 20.43 g (0.15 mol) of MTMS, 56.08 g (0.25 mol) of StTMS, 26.23 g (0.1 mol) of SuTMS, and 130.08 g of PGME were introduced into a flask, and a mixture of 28.80 g of water and 0.514 g of phosphoric acid was added thereto to synthesize a polysiloxane (P-15). The concentration of solids in the PGME solution of the polysiloxane (P-15) was 35.2%. The molar content of styryl groups in the polysiloxane (P-15) measured by ²⁹Si-NMR was 50% by mole.

### Synthesis Example 16. Synthesis of Polysiloxane (P-16)

According to the same procedure as in Synthesis Example 1, 44.86 g (0.2 mol) of StTMS, 73.92 g (0.3 mol) of EpCTMS, and 156.52 g of PGME were introduced into a flask, and a mixture of 27 g of water and 0.594 g of phosphoric acid was added thereto to synthesize a polysiloxane (P-16). The concentration of solids in the PGME solution of the polysiloxane (P-16) was 35.8%. The molar content of styryl groups in the polysiloxane (P-16) measured by ²⁹Si-NMR was 40% by mole.

### Synthesis Example 17. Synthesis of Polysiloxane (P-17)

According to the same procedure as in Synthesis Example 1, 56.08 g (0.25 mol) of StTMS, 61.60 g (0.25 mol) of EpCTMS, and 154.47 g of PGME were introduced into a flask, and a mixture of 27 g of water and 0.588 g of phosphoric acid was added thereto to synthesize a polysiloxane (P-17). The concentration of solids in the PGME solution of the polysiloxane (P-17) was 35.7%. The molar content of styryl groups in the polysiloxane (P-17) measured by ²⁹Si-NMR was 50% by mole.

### Synthesis Example 18. Synthesis of Polysiloxane (P-18)

According to the same procedure as in Synthesis Example 1, 67.29 g (0.3 mol) of StTMS, 49.28 g (0.2 mol) of EpCTMS, and 152.42 g of PGME were introduced into a flask, and a mixture of 27 g of water and 0.583 g of phosphoric acid was added thereto to synthesize a polysiloxane (P-18). The concentration of solids in the PGME solution of the polysiloxane (P-18) was 35.3%. The molar content of styryl groups in the polysiloxane (P-18) measured by ²⁹Si-NMR was 60% by mole.

### Synthesis Example 19. Synthesis of Polysiloxane (P-19)

According to the same procedure as in Synthesis Example 1, 78.51 g (0.35 mol) of StTMS, 36.96 g (0.15 mol) of EpCTMS, and 150.36 g of PGME were introduced into a flask, and a mixture of 27 g of water and 0.577 g of phosphoric acid was added thereto to synthesize a polysiloxane (P-19). The concentration of solids in the PGME solution of the polysiloxane (P-19) was 35.5%. The molar content of styryl groups in the polysiloxane (P-19) measured by ²⁹Si-NMR was 70% by mole.

### Synthesis Example 20. Synthesis of Polysiloxane (P-20)

According to the same procedure as in Synthesis Example 1, 89.72 g (0.4 mol) of StTMS, 24.64 g (0.1 mol) of EpCTMS, and 148.31 g of PGME were introduced into a flask, and a mixture of 27 g of water and 0.572 g of phosphoric acid was added thereto to synthesize a polysiloxane (P-20). The concentration of solids in the PGME solution of the polysiloxane (P-20) was 35.1%. The molar content of styryl groups in the polysiloxane (P-20) measured by ²⁹Si-NMR was 80% by mole.

### Synthesis Example 21. Synthesis of Polysiloxane (P-21)

According to the same procedure as in Synthesis Example 1, 100.94 g (0.45 mol) of StTMS, 12.32 g (0.05 mol) of EpCTMS, and 146.26 g of PGME were introduced into a flask, and a mixture of 27 g of water and 0.566 g of phosphoric acid was added thereto to synthesize a polysiloxane (P-21). The concentration of solids in the PGME solution of the polysiloxane (P-21) was 35.5%. The molar content of styryl groups in the polysiloxane (P-21) measured by ²⁹Si-NMR was 90% by mole.

### Synthesis Example 22. Synthesis of Polysiloxane (P-22)

Into a 500-mL three-neck flask, 29.47 g (0.131 mol) of StTMS, 17.80 g (0.072 mol) of MAcTMS, 9.40 g (0.036 mol) of SuTMS, 1.47 g of a 1% by weight solution of TBC (t-butylpyrocatechol) in DAA, and 59.78 g of DAA were introduced, and the resulting mixture was stirred at room temperature while an aqueous solution of phosphoric acid obtained by dissolving 0.283 g of phosphoric acid (0.50% by weight relative to the introduced monomer) in 13.54 g of water was added thereto over 30 minutes. Subsequently, the resulting mixture was stirred for 90 minutes while the flask was heated in an oil bath at 70° C., and the temperature of the oil bath was then increased to 115° C. over 30 minutes. The internal temperature of the solution reached 100° C. at one hour after starting the temperature rise, and the solution was stirred for further 2 hours with heating (the internal temperature was from 100 to 110° C.) to obtain a polysiloxane (P-22) solution. A nitrogen gas flow was introduced at a rate of 0.05 L (liter) per minute during the temperature rise and the stirring with heating. The by-products, methanol and water, in a total of 29.37 g were distilled off during the reaction. The concentration of solids in the obtained polysiloxane (P-22) solution was 40.6% by weight. The molar contents of styryl groups, (meth)acryloyl groups, and hydrophilic groups in the polysiloxane (P-22) measured by ²⁹Si-NMR were 55% by mole, 30% by mole, and 15% by mole, respectively.

### Synthesis Example 23. Synthesis of Polysiloxane (P-23)

According to the same procedure as in Synthesis Example 22, 38.26 g (0.171 mol) of StTMS, 9.08 g (0.037 mol) of MAcTMS, 9.59 g (0.037 mol) of SuTMS, 1.91 g of a 1% by weight solution of TBC in DAA, and 59.26 g of DAA were introduced into a flask, and an aqueous solution of phosphoric acid obtained by dissolving 0.285 g of phosphoric acid (0.50% by weight relative to the introduced monomer) in 13.81 g of water was added thereto to obtain a polysiloxane (P-23) solution. The concentration of solids in the obtained polysiloxane (P-23) solution was 40.8% by weight. The molar contents of styryl groups, (meth)acryloyl groups, and hydrophilic groups in the polysiloxane (P-23) measured by ²⁹Si-NMR were 70% by mole, 15% by mole, and 15% by mole, respectively.

### Synthesis Example 24. Synthesis of Polysiloxane (P-24)

According to the same procedure as in Synthesis Example 22, 23.59 g (0.105 mol) of StTMS, 20.32 g (0.082 mol) of MAcTMS, 12.26 g (0.047 mol) of SuTMS, 1.18 g of a 1% by weight solution of TBC in DAA, and 60.16 g of DAA were introduced into a flask, and an aqueous solution of phosphoric acid obtained by dissolving 0.281 g of phosphoric acid (0.50% by weight relative to the introduced monomer) in 13.46 g of water was added thereto to obtain a polysiloxane (P-24) solution. The concentration of solids in the obtained polysiloxane (P-24) solution was 40.5% by weight. The molar contents of styryl groups, (meth)acryloyl groups, and hydrophilic groups in the polysiloxane (P-24) measured by ²⁹Si-NMR were 45% by mole, 35% by mole, and 20% by mole, respectively.

### Synthesis Example 25. Synthesis of Polysiloxane (P-25)

According to the same procedure as in Synthesis Example 22, 23.80 g (0.106 mol) of StTMS, 23.42 g (0.094 mol) of MAcTMS, 9.28 g (0.035 mol) of SuTMS, 1.19 g of a 1% by weight solution of TBC in DAA, and 60.12 g of DAA were introduced into a flask, and an aqueous solution of phosphoric acid obtained by dissolving 0.282 g of phosphoric acid (0.50% by weight relative to the introduced monomer) in 13.37 g of water was added to obtain a polysiloxane (P-25) solution. The concentration of solids in the obtained polysiloxane (P-25) solution was 40.5% by weight. The molar contents of styryl groups, (meth)acryloyl groups, and hydrophilic groups in the polysiloxane (P-25) measured by ²⁹Si-NMR were 45% by mole, 40% by mole, and 15% by mole, respectively.

### Synthesis Example 26. Synthesis of Polysiloxane (P-26)

According to the same procedure as in Synthesis Example 22, 35.29 g (0.157 mol) of StTMS, 12.02 g (0.048 mol) of MAcTMS, 9.52 g (0.036 mol) SuTMS, 1.76 g of a 1% by weight solution of TBC in DAA, and 59.44 g of DAA were introduced into a flask, and an aqueous solution of phosphoric acid obtained by dissolving 0.284 g of phosphoric acid (0.50% by weight relative to the introduced monomer) in 13.72 g of water was added thereto to obtain a polysiloxane (P-26) solution. The concentration of solids in the obtained polysiloxane (P-26) solution was 40.7% by weight. The molar contents of styryl groups, (meth)acryloyl groups, and hydrophilic groups in the polysiloxane (P-26) measured by ²⁹Si-NMR were 65% by mole, 20% by mole, and 15% by mole, respectively.

### Synthesis Example 27. Synthesis of Polysiloxane (P-27)

According to the same procedure as in Synthesis Example 22, 35.21 g (0.157 mol) of StTMS, 9.00 g (0.036 mol) of MAcTMS, 12.67 g (0.048 mol) of SuTMS, 244.95 g of the “OPTOLAKE” TR-527 (tradename; manufactured by JGC C&C; having a number-average molecular weight of 15 nm), that is, a 20.5% by weight titanium oxide-silicon oxide composite particle dispersion in methanol (122 parts by weight of particles relative to 100 parts by weight of the completely condensed organosilanes (41.09 g)), 1.76 g of a 1% by weight solution of TBC in DAA, and 59.88 g of DAA were introduced into a flask, and an aqueous solution of phosphoric acid obtained by dissolving 0.284 g of phosphoric acid (0.50% by weight relative to the introduced monomer) in 13.91 g of water was added thereto to obtain a polysiloxane (P-27) solution. The concentration of solids in the obtained polysiloxane (P-27) solution was 40.7% by weight. The molar contents of styryl groups, (meth)acryloyl groups, and hydrophilic groups in the polysiloxane (P-27) measured by ²⁹Si-NMR were 65% by mole, 15% by mole, and 20% by mole, respectively.

### Synthesis Example 28. Synthesis of Polysiloxane (P-28)

According to the same procedure as in Synthesis Example 22, 29.21 g (0.130 mol) of StTMS, 14.70 g (0.059 mol) of MAcTMS, 12.42 g (0.047 mol) of SuTMS, 1.46 g of a 1% by weight solution of TBC in DAA, and 59.83 g of DAA were introduced into a flask, and an aqueous solution of phosphoric acid obtained by dissolving 0.282 g of phosphoric acid (0.50% by weight relative to the introduced monomer) in 13.64 g of water was added thereto to obtain a polysiloxane (P-28) solution. The concentration of solids in the obtained polysiloxane (P-28) solution was 40.6% by weight. The molar contents of styryl groups, (meth)acryloyl groups, and hydrophilic groups in the polysiloxane (P-28) measured by ²⁹Si-NMR were 55% by mole, 25% by mole, and 20% by mole, respectively.

### Synthesis Example 29. Synthesis of a polysiloxane (P-29) solution

According to the same procedure as in Synthesis Example 22, 29.73 g (0.133 mol) of StTMS, 20.95 g (0.084 mol) of MAcTMS, 6.32 g (0.024 mol) of SuTMS, 1.49 g of a 1% by weight solution of TBC in DAA, and 59.73 g of DAA were introduced into a flask, and an aqueous solution of phosphoric acid obtained by dissolving 0.285 g of phosphoric acid (0.50% by weight relative to the introduced monomer) in 13.44 g of water was added thereto to obtain a polysiloxane (P-29) solution. The concentration of solids in the obtained polysiloxane (P-29) solution was 40.6% by weight. The molar contents of styryl groups, (meth)acryloyl groups, and hydrophilic groups in the polysiloxane (P-29) measured by ²⁹Si-NMR were 55% by mole, 35% by mole, and 10% by mole, respectively.

### Synthesis Example 30. Synthesis of Polysiloxane (P-30)

According to the same procedure as in Synthesis Example 22, 30.16 g (0.134 mol) of StTMS, 17.18 g (0.073 mol) of MAcTMS, 9.62 g (0.037 mol) of SuTMS, 2.37 g of a 1% by weight solution of TBC in DAA, and 58.79 g of DAA were introduced into a flask, and an aqueous solution of phosphoric acid obtained by dissolving 0.285 g of phosphoric acid (0.50% by weight relative to the introduced monomer) in 13.86 g of water was added thereto to obtain a polysiloxane (P-30) solution. The concentration of solids in the obtained polysiloxane (P-30) solution was 40.9% by weight. The molar contents of styryl groups, (meth)acryloyl groups, and hydrophilic groups in the polysiloxane (P-30) measured by ²⁹Si-NMR were 55% by mole, 30% by mole, and 15% by mole, respectively.

### Synthesis Example 31. Synthesis of Polysiloxane (P-31)

According to the same procedure as in Synthesis Example 22, 35.86 g (0.160 mol) of StTMS, 11.52 g (0.049 mol) of MAcTMS, 9.67 g (0.037 mol) of SuTMS, 2.37 g of a 1% by weight solution of TBC in DAA, and 58.77 g of DAA were introduced into a flask, and an aqueous solution of phosphoric acid obtained by dissolving 0.285 g of phosphoric acid (0.50% by weight relative to the introduced monomer) in 13.94 g of water was added thereto to obtain a polysiloxane (P-31) solution. The concentration of solids in the obtained polysiloxane (P-31) solution was 40.9% by weight. The molar contents of styryl groups, (meth)acryloyl groups, and hydrophilic groups in the polysiloxane (P-31) measured by ²⁹Si-NMR were 65% by mole, 20% by mole, and 15% by mole, respectively.

### Synthesis Example 32. Synthesis of Polysiloxane (P-32)

According to the same procedure as in Synthesis Example 22, 29.47 g (0.131 mol) of StTMS, 17.80 g (0.072 mol) of MAcTMS, 9.40 g (0.036 mol) of SuTMS, 1.47 g of a 1% by weight solution of TBC in DAA, and 59.78 g of DAA were introduced into a flask, and an aqueous solution of phosphoric acid obtained by dissolving 0.283 g of phosphoric acid (0.50% by weight relative to the introduced monomer) in 13.54 g of water was added thereto to obtain a polysiloxane (P-32) solution. The concentration of solids in the obtained polysiloxane (P-32) solution was 40.6% by weight. The molar contents of styryl groups, (meth)acryloyl groups, and hydrophilic groups in the polysiloxane (P-32) measured by ²⁹Si-NMR were 55% by mole, 30% by mole, and 15% by mole, respectively.

TABLE 1

| | | Raw material alkoxysilanes | | | | | | | |
|---|---|---|---|---|---|---|---|---|---|
| | | | Introduced | | Introduced | | Introduced | | Introduced |
| | | Ingredient | amount | Ingredient | amount | Ingredient | amount | | amount |
| No. | (A) | (a-1) | (mol %) | (a-2) | (mol %) | (a-3) | (mol %) | Others | (mol %) |
| Synthesis Example 1 | P-1 | StTMS | 50 | | | EpCTMS | 10 | MTM | 40 |
| Synthesis Example 2 | P-2 | StTMS | 50 | | | EpCTMS | 10 | PhTMS | 40 |
| Synthesis Example 3 | P-3 | StTMS | 50 | | | EpCTMS | 10 | NaTMS | 40 |
| Synthesis Example 4 | P-4 | StTMS | 50 | AcTMS | 40 | EpCTMS | 10 | | |
| Synthesis Example 5 | P-5 | StTMS | 50 | MAcTMS | 40 | EpCTMS | 10 | | |
| Synthesis Example 6 | P-6 | StTMS | 50 | | | SuTMS | 10 | NaTMS | 40 |
| Synthesis Example 7 | P-7 | StTMS | 50 | AcTMS | 40 | SuTMS | 10 | | |
| Synthesis Example 8 | P-8 | StTMS | 50 | MAcTMS | 40 | SuTMS | 10 | | |
| Synthesis Example 9 | P-9 | StTMS | 40 | AcTMS | 50 | SuTMS | 10 | | |
| Synthesis Example 10 | P-10 | StTMS | 60 | AcTMS | 30 | SuTMS | 10 | | |
| Synthesis Example 11 | P-11 | StTMS | 70 | AcTMS | 20 | SuTMS | 10 | | |
| Synthesis Example 12 | P-12 | StTMS | 80 | AcTMS | 10 | SuTMS | 10 | | |
| Synthesis Example 13 | P-13 | StTMS | 50 | | | SuTMS | 5 | MTMS | 45 |
| Synthesis Example 14 | P-14 | StTMS | 50 | | | SuTMS | 15 | MTMS | 35 |
| Synthesis Example 15 | P-15 | StTMS | 50 | | | SuTMS | 20 | MTMS | 30 |
| Synthesis Example 16 | P-16 | StTMS | 40 | | | EpCTMS | 60 | — | — |
| Synthesis Example 17 | P-17 | StTMS | 50 | | | EpCTMS | 50 | — | — |
| Synthesis Example 18 | P-18 | StTMS | 60 | | | EpCTMS | 40 | — | — |
| Synthesis Example 19 | P-19 | StTMS | 70 | | | EpCTMS | 30 | — | — |
| Synthesis Example 20 | P-20 | StTMS | 80 | | | EpCTMS | 20 | — | — |
| Synthesis Example 21 | P-21 | StTMS | 90 | | | EpCTMS | 10 | — | — |
| Synthesis Example 22 | P-22 | StTMS | 55 | MAcTMS | 30 | SuTMS | 15 | | |
| Synthesis Example 23 | P-23 | StTMS | 70 | MAcTMS | 15 | SuTMS | 15 | | |
| Synthesis Example 24 | P-24 | StTMS | 45 | MAcTMS | 35 | SuTMS | 20 | | |
| Synthesis Example 25 | P-25 | StTMS | 45 | MAcTMS | 40 | SuTMS | 15 | | |
| Synthesis Example 26 | P-26 | StTMS | 65 | MAcTMS | 20 | SuTMS | 15 | | |
| Synthesis Example 27 | P-27 | StTMS | 65 | MAcTMS | 15 | SuTMS | 20 | | |
| Synthesis Example 28 | P-28 | StTMS | 55 | MAcTMS | 25 | SuTMS | 20 | | |
| Synthesis Example 29 | P-29 | StTMS | 55 | MAcTMS | 35 | SuTMS | 10 | | |
| Synthesis Example 30 | P-30 | StTMS | 55 | AcTMS | 30 | SuTMS | 15 | | |
| Synthesis Example 31 | P-31 | StTMS | 65 | AcTMS | 20 | SuTMS | 15 | | |
| Synthesis Example 32 | P-32 | StTMS | 55 | AcTMS | 30 | SuTMS | 15 | | |

### Polymer Synthesis in Comparative Examples

### Synthesis Example 33. Synthesis of Polysiloxane (R-1)

Into a 500-mL three-neck flask, 47.67 g (0.35 mol) of MTMS, 39.66 g (0.20 mol) of PhTMS, 78.52 g (0.35 mol) of StTMS, 26.23 g (0.10 mol) of SuTMS, and 160.47 g of DAA were introduced, and the resulting mixture was stirred while the flask was placed in an oil bath at 40° C. and an aqueous solution of phosphoric acid obtained by dissolving 0.331 g of phosphoric acid (0.2% by weight relative to the introduced monomer) in 55.80 g of water was added to the flask over 10 minutes through a dropping funnel. The resulting mixture was then heated with stirring under the same conditions as those in Synthesis Example 3 and the by-products, methanol and water, in a total of 100 g were distilled off during the reaction. DAA was further added to the obtained DAA solution of a polysiloxane (R-1) to adjust the polymer concentration to 40% by weight and the polysiloxane (R-1) solution was thereby obtained. The molar content of styryl groups in the polysiloxane (R-1) measured by ²⁹Si-NMR was 35% by mole.

### Synthesis Example 34. Synthesis of Polysiloxane (R-2)

Into a 500-mL three-neck flask, 47.67 g (0.35 mol) of MTMS, 39.66 g (0.20 mol) of PhTMS, 26.23 g (0.10 mol) of SuTMS, 82.03 g (0.35 mol) of AcTMS, and 185.08 g of DAA were introduced, and the resulting mixture was stirred while the flask was placed in an oil bath at 40° C. and an aqueous solution of phosphoric acid obtained by dissolving 0.401 g of phosphoric acid (0.2% by weight relative to the introduced monomer) in 55.8 g of water was added to the flask over 10 minutes through a dropping funnel. The resulting mixture was then heated with stirring under the same conditions as those in Synthesis Example 3 and the by-products, methanol and water, in a total of 110 g were distilled off during the reaction. DAA was further added to the obtained DAA solution of a polysiloxane (R-2) to adjust the polymer concentration to 40% by weight and the polysiloxane (R-2) solution was thereby obtained. The molar content of styryl groups in the polysiloxane (R-2) measured by ²⁹Si-NMR was 0% by mole.

### Synthesis Example 35. Synthesis of Polysiloxane (R-3)

Into a 500-mL three-neck flask, 47.67 g (0.35 mol) of MTMS, 39.66 g (0.20 mol) of PhTMS, 26.23 g (0.10 mol) of SuTMS, 87.29 g (0.35 mol) of AcTMS, and 185.40 g of DAA were introduced, and the resulting mixture was stirred while the flask was placed in an oil bath at 40° C. and an aqueous solution of phosphoric acid obtained by dissolving 0.401 g of phosphoric acid (0.2% by weight relative to the introduced monomer) in 55.8 g of water was added to the flask over 10 minutes through a dropping funnel. The resulting mixture was then heated with stirring under the same conditions as those in Synthesis Example 3 and the by-products, methanol and water, in a total of 110 g were distilled off during the reaction. DAA was further added to the obtained DAA solution of a polysiloxane (R-3) to adjust the polymer concentration to 40% by weight and the polysiloxane (R-3) solution was thereby obtained. The molar content of styryl groups in the polysiloxane (R-3) measured by ²⁹Si-NMR was 0% by mole.

### Synthesis Example 36. Synthesis of Polysiloxane (R-4)

Into a 500-mL three-neck flask, 26.23 g (0.10 mol) of SuTMS, 210.93 g (0.90 mol) of AcTMS, and 185.08 g of DAA were introduced, and the resulting mixture was stirred while the flask was placed in an oil bath at 40° C. and an aqueous solution of phosphoric acid obtained by dissolving 0.401 g of phosphoric acid (0.2% by weight relative to the introduced monomer) in 55.8 g of water was added to the flask over 10 minutes through a dropping funnel. The resulting mixture was then heated with stirring under the same conditions as those in Synthesis Example 3 and the by-products, methanol and water, in a total of 110 g were distilled off during the reaction. DAA was further added to the obtained DAA solution of a polysiloxane (R-4) to adjust the polymer concentration to 40% by weight and the polysiloxane (R-4) solution was thereby obtained. The molar content of styryl groups in the polysiloxane (R-4) measured by ²⁹Si-NMR was 0% by mole.

### Synthesis Example 37. Synthesis of Polysiloxane (R-5)

Into a 2-L round-bottom flask equipped with a water-cooled condenser and a stirring blade with a vacuum seal, 540.78 g (2.5 mol) of DPD, 577.41 g (2.325 mol) of MAcTMS, and 24.87 g (0.0875 mol) of TIP were introduced, and the stirring was started. The flask was placed in an oil bath and the heating temperature was set to 120° C. to start heating from room temperature. While methanol generated in association with the progress of the polymerization reaction was recovered by the water-cooled condenser, the reaction was allowed to proceed until the temperature of the reaction solution became constant, and the stirring was continued with heating for further 30 minutes. Subsequently, a hose connected to a cold trap and a vacuum pump was attached to the flask and methanol was distilled off by heating the reaction mixture with strong stirring in an oil bath at 80° C. and simultaneously applying gradually increased vacuum to prevent bumping of methanol, and a polysiloxane (R-5) was thereby obtained. The molar content of styryl groups in the polysiloxane (R-5) measured by ²⁹Si-NMR was 0% by mole.

### Synthesis Example 38. Synthesis of Polysiloxane (R-6)

Into a 100-mL flask, 18 g (75 mmol) of PhTES, 6.7 g (25 mmol) of StTES, 18 g (100 mmol) of MTES, 8.6 g (480 mmol) of pure water, 45 mg of 1 N hydrochloric acid, and 140 mg (1.3 mmol) of hydroquinone were introduced, and the resulting mixture was heated with stirring at 90° C. under ambient atmosphere. The reaction mixture was a heterogeneous system at the beginning of the reaction but became colorless and transparent 5 minutes after the start of heating. Moreover, ethanol started to be distilled off 10 minutes after the start of heating. The reaction was not stopped until 85% of the theoretical amount of ethanol (24 g) was distilled off 2 hours after the start of heating. The reaction mixture was dried for 2 hours under reduced pressure (1 Torr) to remove ethanol in the reaction mixture and 23 g of a polysiloxane (R-6) was obtained as a white powdery solid. The molar content of styryl groups in the polysiloxane (R-6) measured by ²⁹Si-NMR was 12.5% by mole.

### Synthesis Example 39. Synthesis of Polysiloxane (R-7)

Into a 100-mL flask, 19.2 g (80 mmol) of PhTES, 13.4 g (50 mmol) of StTES, 12.6 g (70 mmol) of MTES, 8.6 g (480 mmol) of pure water, 45 mg of 1 N hydrochloric acid, and 140 mg (1.3 mmol) of hydroquinone were introduced, and the resulting mixture was heated with stirring at 90° C. under ambient atmosphere. The reaction mixture was a heterogeneous system at the beginning of the reaction but became colorless and transparent 5 minutes after the start of heating. Moreover, ethanol started to be distilled off 10 minutes after the start of heating. The reaction was not stopped until 85% of the theoretical amount of ethanol (24 g) was distilled off 2 hours after the start of heating. The reaction mixture was dried for 2 hours under reduced pressure (1 Torr) to remove ethanol in the reaction mixture and 23 g of a polysiloxane (R-7) was obtained as a white powdery solid. The molar content of styryl groups in the polysiloxane (R-7) measured by ²⁹Si-NMR was 25% by mole.

### Synthesis Example 40. Synthesis of Polysiloxane (R-8)

According to the same procedure as in Synthesis Example 22, 28.26 g (0.143 mol) of PhTMS, 19.31 g (0.078 mol) of MAcTMS, 10.20 g (0.039 mol) of SuTMS, and 60.88 g of DAA were introduced into a flask, and an aqueous solution of phosphoric acid obtained by dissolving 0.289 g of phosphoric acid (0.50% by weight relative to the introduced monomer) in 14.69 g of water was added thereto to obtain a polysiloxane (R-8) solution. The concentration of solids in the obtained polysiloxane (R-8) solution was 40.0% by weight. The molar contents of styryl groups, (meth)acryloyl groups, and hydrophilic groups in the polysiloxane (R-8) measured by ²⁹Si-NMR were 0% by mole, 30% by mole, and 15% by mole, respectively.

### Synthesis Example 41. Synthesis of Polysiloxane (R-9)

According to the same procedure as in Synthesis Example 22, 24.34 g (0.179 mol) of MTMS, 24.21 g (0.097 mol) of MAcTMS, 12.79 g (0.049 mol) of SuTMS, and 59.70 g of DAA were introduced into a flask, and an aqueous solution of phosphoric acid obtained by dissolving 0.307 g of phosphoric acid (0.50% by weight relative to the introduced monomer) in 18.42 g of water was added to obtain a polysiloxane (R-9) solution. The concentration of solids in the obtained polysiloxane (R-9) solution was 40.0% by weight. The molar contents of styryl groups, (meth)acryloyl groups, and hydrophilic groups in the polysiloxane (R-9) measured by ²⁹Si-NMR were 0% by mole, 30% by mole, and 15% by mole, respectively.

### Synthesis Example 42. Synthesis of Polysiloxane (R-10) Containing Styryl Groups, (Meth)Acryloyl Groups, and Hydrophilic Groups

According to the same procedure as in Synthesis Example 22, 32.87 g (0.147 mol) of StTMS, 19.85 g (0.080 mol) of MAcTMS, 5.44 g (0.040 mol) of MTMS, 1.64 g of a 1% by weight solution of TBC in DAA, and 59.12 g of DAA were introduced into a flask, and an aqueous solution of phosphoric acid obtained by dissolving 0.291 g of phosphoric acid (0.50% by weight relative to the introduced monomer) in 15.10 g of water was added to obtain a polysiloxane (R-10). The concentration of solids in the obtained polysiloxane (R-10) was 40.7% by weight. The molar contents of styryl groups, (meth)acryloyl groups, and hydrophilic groups measured by ²⁹Si-NMR were 55% by mole, 30% by mole, and 15% by mole, respectively.

TABLE 2

| | | Raw material alkoxysilanes | | | | | | | | | |
|---|---|---|---|---|---|---|---|---|---|---|---|
| | | | Introduced | | Introduced | | Introduced | | Introduced | | Introduced |
| | | Ingredient | amount | Ingredient | amount | Ingredient | amount | | amount | | amount |
| No. | (A) | (a-1) | (mol %) | (a-2) | (mol %) | (a-3) | (mol %) | Others | (mol %) | Others | (mol %) |
| Synthesis Example 33 | R-1 | StTMS | 35 | — | — | SuTMS | 10 | MTMS | 35 | PhTMS | 20 |
| Synthesis Example 34 | R-2 | — | — | AcTMS | 35 | SuTMS | 10 | MTMS | 35 | PhTMS | 20 |
| Synthesis Example 35 | R-3 | — | — | MAcTMS | 35 | SuTMS | 10 | MTMS | 35 | PhTMS | 20 |
| Synthesis Example 36 | R-4 | — | — | AcTMS | 90 | SuTMS | 10 | — | — | — | — |
| Synthesis Example 33 | R-5 | — | — | MAcTMS | 47.3 | — | — | TIP | 1.8 | DPD | 50.9 |
| Synthesis Example 37 | R-6 | StTMS | 12.5 | — | — | — | — | MTES | 50 | PhTES | 37.5 |
| Synthesis Example 38 | R-7 | StTMS | 25 | — | — | — | — | MTES | 35 | PhTES | 40 |
| Synthesis Example 39 | R-8 | | | MAcTMS | 30 | SuTMS | 15 | PhTMS | 55 | | |
| Synthesis Example 40 | R-9 | | | MAcTMS | 30 | SuTMS | 15 | MTMS | 55 | | |
| Synthesis Example 41 | R-10 | StTMS | 55 | MAcTMS | 30 | | | MTMS | 15 | | |

### <Solvent Exchange in Metal Compound Particles>

### Example of Solvent Exchange 1: Solvent Exchange in “OPTOLAKE” TR-527

The solvent in the “OPTOLAKE” TR-527 (tradename; manufactured by JGC C&C), a colloidal solution containing metal compound particles, was exchanged from methanol to DAA. Into a 500-mL evaporating flask, 100 g of the colloidal “OPTOLAKE” TR-527 solution in methanol (with a solid concentration of 20%) and 80 g of DAA were introduced, and the methanol in the resulting mixture was removed by heating the flask at 30° C. for 30 minutes under reduced pressure on an evaporator. The measured concentration of solids in the obtained DAA solution of TR-527 (D-1) was 20.1%.

### Example of Solvent Exchange 2: Solvent Exchange in “OPTOLAKE” TR-550

The solvent in the “OPTOLAKE” TR-550 (tradename; manufactured by JGC C&C), a colloidal solution containing metal oxide particles, was exchanged from methanol to DAA, similarly to Example of solvent exchange 1. The measured concentration of solids in the obtained DAA solution of TR-550 (D-2) was 20.1%.

### <Production of a Rugged Substrate>

Under dry nitrogen gas flow, 15.9 g (0.043 mol) of 2,2-bis(3-amino-4-hydroxyphenyl)hexafluoropropane (BAHF; manufactured by Central Glass Co., Ltd.) and 0.62 g (0.0025 mol) of 1,3-bis(3-aminopropyl)tetramethyldisiloxane (SiDA) were dissolved in 200 g of N-methylpyrrolidone (NMP). To the resulting mixture, 15.5 g (0.05 mol) 3,3′,4,4′-diphenylethertetracarboxylicacid dianhydride (ODPA; manufactured by Manac Inc.) and 50 g of N-methylpyrrolidone (NMP) were added, and the resulting mixture was stirred at 40° C. for 2 hours. Subsequently, 1.17 g (0.01 mol) of 4-ethynylaniline (manufactured by Tokyo Chemical Industry Co., Ltd.) was added thereto and the resulting mixture was stirred at 40° C. for 2 hours. A solution obtained by diluting 3.57 g (0.03 mol) of dimethylformamide dimethylacetal (DFA; manufactured by Mitsubishi Rayon Co., Ltd.) in 5 g of N-methylpyrrolidone (NMP) was further added dropwise to the above mixture over a period of 10 minutes, and the resulting mixture was continued to be stirred at 40° C. for 2 hours after the dropwise addition. After completion of stirring, the resulting solution was poured into 2 L of water and solid polymer precipitates were collected by filtration. The collected polymer solids were further washed with 2 L of water three times and then dried in a vacuum dryer at 50° C. for 72 hours to obtain a polyamic acid ester A.

Under dry nitrogen gas flow, 21.23 g (0.05 mol) of TrisP-PA (tradename; manufactured by Honshu Chemical Industry Co., Ltd.) and 37.62 g (0.14 mol) of 5-naphthoquinonediazidesulfonyl chloride were dissolved in 450 g of 1,4-dioxane, and the resulting mixture was left to room temperature. A mixture of 15.58 g (0.154 mol) of triethylamine and 50 g of 1,4-dioxane was added dropwise to the above mixture to prevent the temperature in the system from exceeding 35° C. After the dropwise addition, the resulting mixture was stirred at 30° C. for 2 hours. The generated triethylamine salt was filtered and the filtrate was poured into water. Subsequently, precipitates were collected by filtration. The precipitates were dried with a vacuum dryer to obtain a naphthoquinonediazide compound A having the following structure.

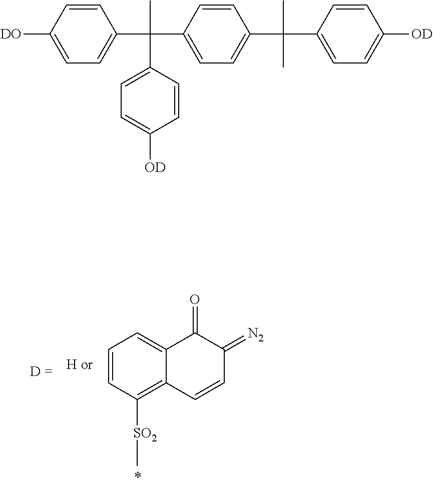

Under a yellow lamp, 10.00 g (100 parts by weight) of the polyamic acid ester A, 3.00 g (30 parts by weight) of the naphthoquinonediazide compound A, 0.01 g (0.1 parts by weight) of diphenyldimethoxysilane (KBM-202SS; manufactured by Shin-Etsu Chemical Co., Ltd.), 0.50 g (0.5 parts by weight) of 1,1,1-Tris(4-hydroxyphenyl)ethane (TrisP-HAP; manufactured by Honshu Chemical Industry Co., Ltd.) as a phenolic hydroxyl group-containing compound, and γ-butyrolactone (GBL) as a solvent in an amount that was enough to achieve a solid concentration of 20% by weight in an obtained composition (52.04 g) were mixed and stirred to obtain a homogeneous solution, and the obtained homogeneous solution was then filtered through a 0.20-μm filter to prepare a positive photosensitive resin composition.

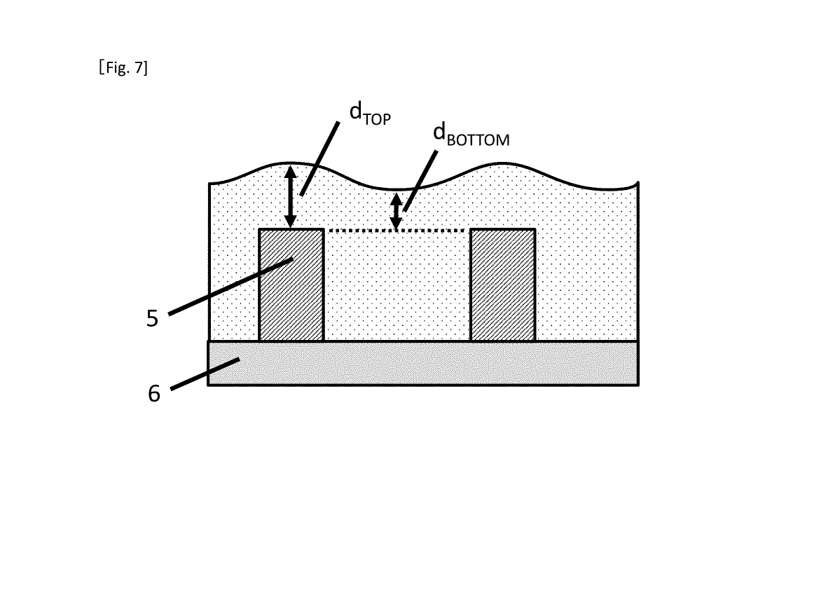

The above-described positive photosensitive resin composition was applied on a silicon wafer of 8 inch in diameter by spin coating using a spin coater (model “Clean Track Mark 7”; manufactured by Tokyo Electron Ltd.) and then pre-baked at 120° C. for 3 minutes by using a hot plate (HP-1SA; manufactured by As One Corporation) to produce a photosensitive resin film with a film thickness of 1.2 μm. The produced photosensitive resin film was exposed to i-line light at an exposure dose of 300 mJ/cm² with an i-line stepper (NSR-2009i9C; manufactured by Nikon Corporation). A quartz glass mask that would provide a rugged pattern as shown in FIGS. 5 and 6 was used as a mask. After exposure to light, the photosensitive resin film was developed in a shower of 2.38% by weight tetramethylammonium hydroxide in water for 60 seconds by using an automatic developing machine (AD-2000; manufactured by Takizawa Sangyo Co., Ltd.) and then rinsed in water for 30 seconds. Subsequently, the developed photosensitive resin film was cured at 230° C. for 30 minutes in an oven (DN43HI; manufactured by Yamato Scientific Co., Ltd.) to obtain a rugged substrate.

FIG. 5 and FIG. 6 show the profile of the levels. FIG. 5 is a top view of a substrate with different levels, which are a convex portion consisting of a cured film pattern 5 made of the positive photosensitive resin composition and a concave portion consisting of the silicon wafer 6, and FIG. 6 is a cross-sectional view taken along line A-A′ in FIG. 5.

### <Production of a Cured Film>

The polysiloxane resin compositions of the respective Examples and Comparative Examples were each applied on a silicon wafer of 8 inch in diameter and the above-described rugged substrate by using a spin coater (model “Clean Track Mark 7”; manufactured by Tokyo Electron Ltd.). In cases where the resin composition was a non-photosensitive composition, the resin composition was pre-baked at 100° C. for 3 minutes after the application and was further cured at 230° C. for 5 minutes to obtain a cured film with a thickness of about 1 μm. In cases where the resin composition was a photosensitive composition, the resin composition was pre-baked at 100° C. for 3 minutes after the application and was then exposed to i-line light at an exposure dose of 400 mJ/cm² with an i-line stepper exposure machine. Subsequently, the resin composition was developed in a shower of 0.4% by weight tetramethylammonium hydroxide in water for 90 seconds and then rinsed in water for 30 seconds. The resin composition was further dried by heating at 100° C. for 3 minutes and finally cured at 230° C. for 5 minutes to obtain a cured film with a thickness of about 1 μm.

### <Measurement of Film Shrinkage Ratio>

The coated film of the resin composition formed on the silicon wafer was measured for film thickness by using the Lambda Ace STM-602 (tradename; manufactured by Dainippon Screen Mfg. Co., Ltd.). In cases where the resin composition was a non-photosensitive composition, the resin composition was applied and pre-baked at 100° C. for 3 minutes to obtain a film and the resulting film was marked with five circles having a diameter of around 5 mm by using forceps and the film thickness was then measured at the center of each circle and the average of the measured values was considered as the film thickness X. Subsequently, the film was cured at 230° C. for 5 minutes and the film thickness was then measured at the center of each circle and the average of the measured values was considered as the film thickness Y. The film shrinkage ratio, (X−Y)/X×100[%], was calculated from these film thickness values X and Y.

On the other hand, in cases where the resin composition was a photosensitive composition, the resin composition was applied and pre-baked at 100° C. for 3 minutes and then exposed to i-line light at an exposure dose of 400 mJ/cm² with an i-line stepper exposure machine. Subsequently, the resin composition was developed in a shower of 0.4% by weight tetramethylammonium hydroxide in water for 90 seconds and then rinsed in water for 30 seconds. The resin composition was further dried by heating at 100° C. for 3 minutes and then marked with five circles having a diameter of around 5 mm by using forceps and the film thickness was then measured at the center of each circle and the average of the measured values was considered as the film thickness X′. Subsequently, the film was cured at 230° C. for 5 minutes and the film thickness was then measured at the center of each circle and the average of the measured values was considered as the film thickness Y. The film shrinkage ratio, (X′−Y)/X′×100[%], was calculated from these film thickness values X′ and Y.

### <Measurement of Film Thickness on a Rugged Substrate>

A notch was formed in the rugged substrate coated with the cured film to provide a film cross section as shown in FIG. 7. This film cross section was observed on the field emission-type scanning electron microscope (FE-SEM) S-4800 (manufactured by Hitachi High-Technologies Corporation) under an acceleration voltage of 3 kV. The d_{TOP} and d_{BOTTOM} values were each measured at a magnification of approximately 10,000 to 50,000 times and the value dBoTTom/d_{TOP}×100[%] was calculated. The film thickness was measured at each center of convex and concave portions at three different positions, and the average values were taken as the d_{TOP} and the d_{BOTTOM}. A position at the center of the substrate and positions adjacent to the left and right sides of the central position were selected as the above-described three positions. For the value (d_{BOTTOM}/d_{TOP}×100), values of not less than 80 was judged excellent (A) in flatness, 70 or more was judged good (B), 60 or more was judged fair (C), and less than 60 was judged poor (D).

### <Coating Properties>

The coated film formed on the silicon wafer was cured at 230° C. for 5 minutes and the resulting cured film was checked by visual observation. Cases where no contamination or irregularity was observed in the cured film were judged excellent (A); cases where no contamination but any minor irregularity in the cured film, such as an irregularity produced by a vacuum chuck in a spin coater or an irregularity produced by pins of a hot plate, was observed were judged fair (B); and cases where any contamination or any severe irregularity in the cured film, such as striations or an overall irregularity was observed were judged poor (C).

### <Storage Stability>

After storing the resin composition in an incubator at 40° C. for 3 days, the resin composition was applied on a silicon wafer and the film thickness X was compared between films prepared with the resin compositions before and after the storage. A change in film thickness of not more than 5% and a change in film thickness of more than 5% were determined to be fair (∘) and poor (x), respectively.

### Example 1

Under a yellow lamp, 7.05 g of the PGME solution (35.2%) of the polysiloxane (P-1) as a polysiloxane (A), and 0.45 g of PGME and 2.5 g of DAA as a solvent (E) were mixed, and the resulting mixture was stirred by shaking and then filtered through a 0.2-μm filter to obtain a resin composition 1. The composition is presented in Table 3.

The produced composition 1 was used to measure the film thickness values X and Y according to the above-described method and then determine the film shrinkage ratio or to measure the d_{TOP} and d_{BOTTOM} values and then calculate the value d_{BOTTOM}/d_{TOP}×100[%]. The evaluation result is presented in Table 4.

### Examples 2 to 21

Resin compositions were prepared according to the list of ratios shown in Table 3 by the same procedure as in Example 1 and the respective resin compositions were evaluated. The results are presented in Table 4.

### Example 22

Under a yellow lamp, 5.64 g of the PGME solution (35.4%) of the polysiloxane (P-6) as a polysiloxane (A), 1.36 g of PGME and 0.5 g of DAA as a solvent (E), and 2.5 g of the DAA solution of TR-527 (D-1) as metal compound particles (D) were introduced and mixed, and the resulting mixture was stirred by shaking and then filtered through a 0.2-μm filter to obtain a resin composition 23. The composition is presented in Table 3. Subsequently, the resin composition was evaluated by the same procedure as in Example 1. The result is presented in Table 4.

### Examples 23 to 25

The resin compositions of Examples 23 to 25 were prepared according to the list of ratios shown in Table 3 by the same procedure as in Example 22 and the respective resin compositions were then evaluated by the same procedure as in Example 1. The results are presented in Table 4.

### Example 26

Under a yellow lamp, 4.94 g of the PGME solution (35.4%) of the polysiloxane (P-6) as a polysiloxane (A), 0.06 g of PGME and 2.5 g of DAA as a solvent (E), and 2.5 g of PGM-ST (PGME colloidal solution; a solid concentration of 30%; manufactured by Nissan Chemical Co.) as metal compound particles (D) were introduced and mixed, and the resulting mixture was stirred by shaking and then filtered through a 0.2-μm filter to obtain a composition. The composition is presented in Table 3. Subsequently, the resin composition was evaluated by the same procedure as in Example 1. The result is presented in Table 4.

### Example 27

Under a yellow lamp, 6.76 g of the PGME solution (35.5%) of the polysiloxane (P-10) as a polysiloxane (A), 1.14 g of PGME and 2.5 g of DAA as a solvent (E), and 0.1 g of 1-[4-(phenylthio)]-1,2-octanedione 2-(O-benzoyloxime) (OXE-01; manufactured by BASF) as a photosensitizer (C) were introduced and mixed, and the resulting mixture was stirred by shaking and then filtered through a 0.2-μm filter to obtain a composition. The composition is presented in Table 3.

The obtained resin composition was applied on the rugged substrate and a silicon wafer by spin coating and then pre-baked at 100° C. for 3 minutes by using a hot plate and exposed to i-line light at an exposure dose of 400 mJ/cm² with an i-line stepper exposure machine (model NSR2005i9C; manufactured by Nikon Corporation). Subsequently, the resin composition was developed in a shower of 0.4% by weight tetramethylammonium hydroxide in water (ELM-D; manufactured by Mitsubishi Gas Chemical Company, Inc.) for 90 seconds by using an automatic developing machine (AD-2000; manufactured by Takizawa Sangyo Co., Ltd.) and then rinsed in water for 30 seconds. The developed film was further dried at 100° C. for 3 minutes and the film thickness X′ was then measured. The film was further cured at 230° C. for 5 minutes by using a hot plate to produce a cured film and the film thickness Y was then measured. The obtained values X′ and Y were used to calculate the film shrinkage ratio. Moreover, the d_{TOP} and d_{BOTTOM} values were measured according to the above-described method in the cured film formed on the rugged substrate to calculate the value d_{BOTTOM}/d_{TOP}×100[%]. The result is presented in Table 4.

### Example 28

A composition was prepared and evaluated, except that the photosensitizer (C) in Example 27 was replaced by bis(2,4,6-trimethylbenzoyl)-phenylphosphine oxide (IC-819; manufactured by Ciba Specialty Chemicals plc.). The composition is presented in Table 3 and the evaluation result is presented in Table 4.

### Example 29

A composition was prepared and evaluated, except that the photosensitizer (C) in Example 27 was replaced by 2-methyl-[4-(methylthio)phenyl]-2-morpholinopropan-1-one (IC-907; manufactured by Ciba Specialty Chemicals plc.). The composition is presented in Table 3 and the evaluation result is presented in Table 4.

### Example 30

A composition was prepared and evaluated, except that the polysiloxane (A) in Example 27 was replaced by the polysiloxane (P-14). The composition is presented in Table 3 and the evaluation result is presented in Table 4.

TABLE 3

| | (I) Resin composition | | | | | | | | |
|---|---|---|---|---|---|---|---|---|---|
| | | | | | | Metal | | | |
| | Resin | | | | | compound | | | |
| | composition | Polysiloxane | Ratio | Photosensitizer | Ratio | particles | Ratio | Solvent | Ratio |
| No. | name | (A) | (wt %) | (C) | (wt %) | (D) | (wt %) | (E) | (wt %) |
| Example 1 | Composition 1 | P-1 | 25 | — | — | — | — | PGME/DAA | 50/25 |
| Example 2 | Composition 2 | P-2 | 25 | — | — | — | — | PGME/DAA | 50/25 |
| Example 3 | Composition 3 | P-3 | 25 | — | — | — | — | PGME/DAA | 50/25 |
| Example 4 | Composition 4 | P-4 | 25 | — | — | — | — | PGME/DAA | 50/25 |
| Example 5 | Composition 5 | P-5 | 25 | — | — | — | — | PGME/DAA | 50/25 |
| Example 6 | Composition 6 | P-6 | 25 | — | — | — | — | PGME/DAA | 50/25 |
| Example 7 | Composition 7 | P-7 | 25 | — | — | — | — | PGME/DAA | 50/25 |
| Example 8 | Composition 8 | P-8 | 25 | — | — | — | — | PGME/DAA | 50/25 |
| Example 9 | Composition 9 | P-9 | 25 | — | — | — | — | PGME/DAA | 50/25 |
| Example 10 | Composition 10 | P-10 | 25 | — | — | — | — | PGME/DAA | 50/25 |
| Example 11 | Composition 11 | P-11 | 25 | — | — | — | — | PGME/DAA | 50/25 |
| Example 12 | Composition 12 | P-12 | 25 | — | — | — | — | PGME/DAA | 50/25 |
| Example 13 | Composition 13 | P-13 | 25 | — | — | — | — | PGME/DAA | 50/25 |
| Example 14 | Composition 14 | P-14 | 25 | — | — | — | — | PGME/DAA | 50/25 |
| Example 15 | Composition 15 | P-15 | 25 | — | — | — | — | PGME/DAA | 50/25 |
| Example 16 | Composition 16 | P-16 | 25 | — | — | — | — | PGME/DAA | 50/25 |
| Example 17 | Composition 17 | P-17 | 25 | — | — | — | — | PGME/DAA | 50/25 |
| Example 18 | Composition 18 | P-18 | 25 | — | — | — | — | PGME/DAA | 50/25 |
| Example 19 | Composition 19 | P-19 | 25 | — | — | — | — | PGME/DAA | 50/25 |
| Example 20 | Composition 20 | P-20 | 25 | — | — | — | — | PGME/DAA | 50/25 |
| Example 21 | Composition 21 | P-21 | 25 | — | — | — | — | PGME/DAA | 50/25 |
| Example 22 | Composition 22 | P-6 | 20 | — | — | D-1 | 5 | PGME/DAA | 50/25 |
| Example 23 | Composition 23 | P-6 | 17.5 | — | — | D-1 | 7.5 | PGME/DAA | 45/30 |
| Example 24 | Composition 24 | P-6 | 15 | — | — | D-1 | 10 | PGME/DAA | 35/40 |
| Example 25 | Composition 25 | P-6 | 12.5 | — | — | D-1 | 12.5 | PGME/DAA | 25/50 |
| Example 26 | Composition 26 | P-6 | 17.5 | — | — | PGM-ST | 7.5 | PGME/DAA | 50/25 |
| Example 27 | Composition 27 | P-10 | 24 | OXE-01 | 1 | — | — | PGME/DAA | 50/25 |
| Example 28 | Composition 28 | P-10 | 24 | IC-819 | 1 | — | — | PGME/DAA | 50/25 |
| Example 29 | Composition 29 | P-10 | 24 | IC-907 | 1 | — | — | PGME/DAA | 50/25 |
| Example 30 | Composition 30 | P-14 | 24 | OXE-01 | 1 | — | — | PGME/DAA | 50/25 |

TABLE 4

| | Film | Film | | | | | | | |
|---|---|---|---|---|---|---|---|---|---|
| | thickness | thickness | Shrinkage | Film thickness on different levels | | | | | |
| | X, X′ | Y | ratio | d_{TOP} | d_{BOTTOM} | d_{BOTTOM}/d_{TOP} | | Coating | Storage |
| No. | (nm) | (nm) | (%) | [nm] | [nm] | [%] | Flatness | properties | stability |
| Example 1 | 1004 | 970 | 3.4 | 201 | 164 | 81.6 | A | B | ∘ |
| Example 2 | 1011 | 978 | 3.3 | 202 | 166 | 82.2 | A | B | ∘ |
| Example 3 | 992 | 959 | 3.3 | 199 | 163 | 81.9 | A | B | ∘ |
| Example 4 | 994 | 960 | 3.4 | 198 | 161 | 81.3 | A | B | ∘ |
| Example 5 | 1008 | 974 | 3.4 | 202 | 164 | 81.2 | A | B | ∘ |
| Example 6 | 1055 | 1019 | 3.4 | 212 | 173 | 81.6 | A | B | ∘ |
| Example 7 | 1024 | 988 | 3.5 | 205 | 166 | 81.0 | A | B | ∘ |
| Example 8 | 1022 | 986 | 3.5 | 206 | 167 | 81.1 | A | B | ∘ |
| Example 9 | 1005 | 960 | 4.5 | 202 | 148 | 73.3 | B | B | ∘ |
| Example 10 | 987 | 959 | 2.8 | 197 | 168 | 85.3 | A | B | ∘ |
| Example 11 | 980 | 956 | 2.4 | 191 | 169 | 88.5 | A | B | ∘ |
| Example 12 | 997 | 976 | 2.1 | 200 | 182 | 91.0 | A | B | ∘ |
| Example 13 | 1009 | 976 | 3.3 | 204 | 166 | 81.4 | A | B | ∘ |
| Example 14 | 1015 | 980 | 3.4 | 205 | 166 | 81.0 | A | A | ∘ |
| Example 15 | 998 | 963 | 3.5 | 199 | 162 | 81.4 | A | A | ∘ |
| Example 16 | 989 | 945 | 4.4 | 197 | 145 | 73.6 | B | A | ∘ |
| Example 17 | 985 | 952 | 3.4 | 194 | 158 | 81.4 | A | A | ∘ |
| Example 18 | 1009 | 980 | 2.9 | 204 | 174 | 85.3 | A | A | ∘ |
| Example 19 | 1001 | 976 | 2.5 | 201 | 178 | 88.6 | A | A | ∘ |
| Example 20 | 1044 | 1021 | 2.2 | 212 | 193 | 91.0 | A | A | ∘ |
| Example 21 | 997 | 977 | 2.0 | 198 | 182 | 91.9 | A | B | ∘ |
| Example 22 | 1011 | 976 | 3.5 | 206 | 167 | 81.1 | A | A | ∘ |
| Example 23 | 995 | 960 | 3.5 | 203 | 163 | 80.3 | A | A | ∘ |
| Example 24 | 989 | 952 | 3.7 | 202 | 159 | 78.7 | B | A | ∘ |
| Example 25 | 973 | 935 | 3.9 | 199 | 153 | 76.9 | B | A | ∘ |
| Example 26 | 989 | 954 | 3.5 | 205 | 165 | 80.5 | A | A | ∘ |
| Example 27 | 1032 | 1003 | 2.8 | 213 | 180 | 84.5 | A | A | ∘ |
| Example 28 | 1011 | 985 | 2.6 | 201 | 169 | 84.1 | A | A | ∘ |
| Example 29 | 1020 | 990 | 2.9 | 208 | 175 | 84.1 | A | A | ∘ |
| Example 30 | 1021 | 986 | 3.4 | 209 | 170 | 81.3 | A | A | ∘ |

### Comparative Example 1

Under a yellow lamp, 0.5166 g of 2-methyl-[4-(methylthio)phenyl]-2-morpholinopropan-1-one (tradename: “IRGACURE 907”; manufactured by Ciba Specialty Chemicals plc.) as an ingredient (C) and 0.0272 g of 4,4-bis(diethylamino)benzophenone were dissolved in 2.9216 g of DAA and 2.4680 g of PGMEA. To the mixture, 6.7974 g of the polysiloxane solution (R-1) as an ingredient (A), 2.7189 g of a 50% by weight solution of 9,9-bis[4-(2-acryloyloxyethoxy)phenyl]fluorene (tradename: “BPEFA”; manufactured by Osaka Gas Chemicals Co., Ltd.) as an ingredient (B) in PGMEA, 2.7189 g of a 50% by weight solution of dipentaerythritolhexaacrylate (tradename: “Kayarad (registered trademark) DPHA”; manufactured by Nippon Kayaku Co., Ltd.) in PGMEA, 1.6314 g of a 1% by weight solution of 4-t-butylcatechol in PGMEA, and 0.2000 g of a 1% by weight solution of BYK-333 (manufactured by BYK Japan KK) as a silicone-based surfactant in PGMEA (corresponding to a concentration of 100 ppm) were added, and the resulting mixture was stirred. Subsequently, the mixture was filtered through a 0.45-μm filter to obtain a comparative composition 1.

The obtained resin composition was applied on the rugged substrate and a silicon wafer by spin coating and then pre-baked at 100° C. for 3 minutes by using a hot plate and exposed to i-line light at an exposure dose of 400 mJ/cm² with an i-line stepper exposure machine (model NSR2005i9C; manufactured by Nikon Corporation). Subsequently, the resin composition was developed in a shower of 0.4% by weight tetramethylammonium hydroxide in water (ELM-D; manufactured by Mitsubishi Gas Chemical Company, Inc.) for 90 seconds by using an automatic developing machine (AD-2000; manufactured by Takizawa Sangyo Co., Ltd.) and then rinsed in water for 30 seconds. The developed film was further dried at 100° C. for 3 minutes and the film thickness X′ was then measured. The film was further cured at 230° C. for 5 minutes by using a hot plate to produce a cured film and the film thickness Y was then measured. The obtained values X′ and Y were used to calculate the film shrinkage ratio. Moreover, the d_{TOP} and d_{BOTTOM} values were measured according to the above-described method in the cured film formed on the rugged substrate to calculate the value d_{BOTTOM}/d_{TOP}×100[%]. The composition of the resin composition is presented in Table 5 and the evaluation result is presented in Table 6.

### Comparative Examples 2 to 4

The resin compositions of Comparative Examples 2 to 4 were prepared and evaluated by the same procedures as in Comparative Example 1 except for using the respective polysiloxanes (R-2), (R-3) and (R-4) instead of the polysiloxane (R-1) and those resin compositions were evaluated similarly to Comparative Example 1. The compositions of the resin compositions are presented in Table 5 and the evaluation results are presented in Table 6.

### Comparative Examples 5 to 7

The resin compositions having the compositions shown in Table 5 were prepared by using the respective polysiloxanes (R-1), (R-3) and (R-4). The resin compositions were evaluated under the same conditions as in Example 1. The evaluation results are presented in Table 6.

### Comparative Example 8

One hundred parts by mass of the polysiloxane R-5 as an ingredient (A) obtained in Synthesis Example 37, 4 parts by mass of 2-benzyl-2-dimethylamino-1-(4-morpholinophenyl)-1-butanone (IRGACURE 369; manufactured by Ciba Specialty Chemicals plc.) as an ingredient (C), and 0.5 parts by mass of 4,4′-bis(diethylamino)benzophenone were mixed with 25 parts by mass of 1,4-bis(3-mercaptobutyryloxy)butane (Karenz MT BD1; manufactured by Showa Denko K.K.), 30 parts by mass of polytetramethyleneglycol dimethacrylate (the number of tetramethyleneglycol units: 8; PDT-650; manufactured by NOF Corporation), 30 parts by mass of MAcTMS, 150 parts by mass of silicone resin (217 flake; manufactured by Dow Corning Toray Co., Ltd.), and 40 parts by mass of N-methyl-2-pyrrolidone as other ingredients. Subsequently, the mixture was diluted three times with PGMEA and the resulting mixture was filtered through a 0.2-μm filter made of “Teflon” (registered trademark) to obtain a comparative composition 8.

The obtained resin composition was applied on a silicon wafer of 8 inch in diameter by using a spin coater (model “Clean Track Mark 7”; manufactured by Tokyo Electron Ltd.) and then pre-baked at 100° C. for 3 minutes. This coated film was exposed to i-line light at an exposure dose of 400 mJ/cm² with an i-line stepper exposure machine (model NSR2005i9C; manufactured by Nikon Corporation). Subsequently, the resin composition was developed in a shower of 0.4% by weight tetramethylammonium hydroxide in water (ELM-D; manufactured by Mitsubishi Gas Chemical Company, Inc.) for 90 seconds by using an automatic developing machine (AD-2000; manufactured by Takizawa Sangyo Co., Ltd.) and then rinsed in water for 30 seconds. The developed film was further dried at 100° C. for 3 minutes and the film thickness X′ was then measured. The film was further cured at 230° C. for 5 minutes by using a hot plate to produce a cured film and the film thickness Y was then measured. The obtained values X′ and Y were used to calculate the film shrinkage ratio. Moreover, the d_{TOP} and d_{BOTTOM} values were measured according to the above-described method in the cured film formed on the substrate with different levels to calculate the value d_{BOTTOM}/d_{TOP}×100[%]. The composition of the resin composition is presented in Table 5 and the evaluation result is presented in Table 6.

### Comparative Example 9

A resin composition having the composition shown in Table 5 was prepared by using the polysiloxane (R-5). The resin composition was evaluated under the same conditions as in Example 1. The evaluation result is presented in Table 6.

### Comparative Example 10

The polysiloxane (R-6) in an amount of 4.5 g was completely dissolved in 4.0 g of THF, and 135 mg of diisopropoxy-bis(acetylacetone) titanium as a silanol condensation catalyst and 171 mg of water were added thereto, and the resulting mixture was mixed by shaking. Then, 380 mg (2.0 mmol) of 1,4-bis(dimethylsylyl)benzene, 4.0×10⁻⁴ mmol of platinum-vinylsiloxane complex (1.54×10⁻⁴ mmol/mg), 4.0×10⁻⁴ mmol of dimethyl maleate as a storage stabilizer and 1.0 g of THF were introduced into another container and then mixed by gentle shaking. The two solutions prepared by the above-described procedures were completely mixed and the resulting mixture was diluted twice by adding PGMEA and then filtered through a 0.45-μm filter to obtain a comparative composition 10. Subsequently, the resin composition was evaluated under the same conditions as in Example 1. The composition is presented in Table 5 and the evaluation result is presented in Table 6.

### Comparative Examples 11 to 12

The resin compositions having the compositions shown in Table 5 were prepared by using the respective polysiloxanes (R-6) and (R-7). The resin compositions were evaluated under the same conditions as in Example 1. The evaluation results are presented in Table 6.

TABLE 5

| | (I) Resin composition | | | | | |
|---|---|---|---|---|---|---|
| | | | | Compound | | |
| | | | | having a radical | | |
| | | | | polymerizable | | |
| | Resin | | | group and an | | |
| | composition | Polysiloxane | Ratio | aromatic ring | Ratio | Photosensitizer |
| No. | name | (A) | (wt %) | (B) | (wt %) | (C) |
| Comparative | Comparative | R-1 | 13.6 | BPEFA | 6.8 | IRGACURE 907/ |
| Example 1 | Composition 1 | | | | | 4,4- |
| | | | | | | bis(diethylamino)- |
| | | | | | | benzophenone |
| Comparative | Comparative | R-2 | 13.6 | BPEFA | 6.8 | IRGACURE 907/ |
| Example 2 | Composition 2 | | | | | 4,4- |
| | | | | | | bis(diethylamino)- |
| | | | | | | benzophenone |
| Comparative | Comparative | R-3 | 13.6 | BPEFA | 6.8 | IRGACURE 907/ |
| Example 3 | Composition 3 | | | | | 4,4- |
| | | | | | | bis(diethylamino)- |
| | | | | | | benzophenone |
| Comparative | Comparative | R-4 | 13.6 | BPEFA | 6.8 | IRGACURE 907/ |
| Example 4 | Composition 4 | | | | | 4,4- |
| | | | | | | bis(diethylamino)- |
| | | | | | | benzophenone |
| Comparative | Comparative | R-1 | 25 | — | — | — |
| Example 5 | Composition 5 | | | | | |
| Comparative | Comparative | R-3 | 25 | — | — | — |
| Example 6 | Composition 6 | | | | | |
| Comparative | Comparative | R-4 | 25 | — | — | — |
| Example 7 | Composition 7 | | | | | |
| Comparative | Comparative | R-5 | 26.4 | — | — | IRGACURE 907/ |
| Example 8 | Composition 8 | | | | | 4,4- |
| | | | | | | bis(diethylamino)- |
| | | | | | | benzophenone |
| Comparative | Comparative | R-5 | 25 | — | — | — |
| Example 9 | Composition 9 | | | | | |
| Comparative | Comparative | R-6 | 43.9 | — | — | — |
| Example 10 | Composition 10 | | | | | |
| Comparative | Comparative | R-6 | 25 | — | — | — |
| Example 11 | Composition 11 | | | | | |
| Comparative | Comparative | R-7 | 25 | — | — | — |
| Example 12 | Composition 12 | | | | | |

| | (I) Resin composition | | | | |
|---|---|---|---|---|---|
| | Ratio | Solvent | Ratio | | Ratio |
| No. | (wt %) | (E) | (wt %) | Others | (wt %) |
| Comparative | 2.6/0.1 | DAA/PGMEA | 35/35 | DPHA/4-t- | 6.8/0.1 |
| Example 1 | | | | butylcatachol | |
| Comparative | 2.6/0.1 | DAA/PGMEA | 35/35 | DPHA/4-t- | 6.8/0.1 |
| Example 2 | | | | butylcatachol | |
| Comparative | 2.6/0.1 | DAA/PGMEA | 35/35 | DPHA/4-t- | 6.8/0.1 |
| Example 3 | | | | butylcatachol | |
| Comparative | 2.6/0.1 | DAA/PGMEA | 35/35 | DPHA/4-t- | 6.8/0.1 |
| Example 4 | | | | butylcatachol | |
| Comparative | — | DAA/PGMEA | 37.5/37.5 | — | — |
| Example 5 | | | | | |
| Comparative | — | DAA/PGMEA | 37.5/37.5 | — | — |
| Example 6 | | | | | |
| Comparative | — | DAA/PGMEA | 37.5/37.5 | — | — |
| Example 7 | | | | | |
| Comparative | 1.1/0.1 | NMP/PGMEA | 10.5/200 | Karenz MT BD1/PDT-650/ | 6.6/7.9/ |
| Example 8 | | | | MAcTMS/217 Flake | 7.9/39.5 |
| Comparative | — | NMP | 75 | — | — |
| Example 9 | | | | | |
| Comparative | — | THF/PGMEA | 48.8/100 | titanium diisopropoxy- | 1.3/1.7/ |
| Example 10 | | | | bisacetylacetone/water/1,4- | 3.7/0.6/ |
| | | | | bis(dimethylsilyl)benzene/ | 25 ppm |
| | | | | dimethyl maleate/platinum | |
| | | | | vinylsiloxane complex | |
| Comparative | — | THF | 75 | — | — |
| Example 11 | | | | | |
| Comparative | — | THF | 75 | — | — |
| Example 12 | | | | | |

TABLE 6

| | Film | Film | | Film thickness on different levels | | | | | |
|---|---|---|---|---|---|---|---|---|---|
| | thickness | thickness | Shrinkage | | | d_{BOTTOM}/ | | | |
| | X | Y | ratio | d_{TOP} | d_{BOTTOM} | d_{TOP} × 100 | | Coating | Storage |
| No. | (nm) | (nm) | (%) | [nm] | [nm] | [%] | Flatness | properties | stability |
| ComparativeExample 1 | 1014 | 915 | 9.8 | 204 | 86 | 42.2 | D | A | ∘ |
| ComparativeExample 2 | 1021 | 917 | 10.2 | 205 | 87 | 42.4 | D | A | ∘ |
| ComparativeExample 3 | 1024 | 923 | 9.9 | 207 | 89 | 43.0 | D | A | ∘ |
| ComparativeExample 4 | 1051 | 947 | 9.9 | 211 | 90 | 42.7 | D | A | ∘ |
| ComparativeExample 5 | 1033 | 974 | 5.7 | 209 | 135 | 64.6 | C | A | ∘ |
| ComparativeExample 6 | 1018 | 911 | 10.5 | 208 | 91 | 43.8 | D | A | ∘ |
| Comparative Example 7 | 1010 | 905 | 10.4 | 205 | 89 | 43.4 | D | A | ∘ |
| Comparative Example 8 | 1013 | 962 | 5.0 | 203 | 146 | 71.9 | B | B | x |
| Comparative Example 9 | 1034 | 925 | 10.5 | 209 | 86 | 41.1 | D | C | ∘ |
| Comparative Example 10 | 1008 | 900 | 10.7 | 201 | 86 | 42.8 | D | C | x |
| Comparative Example 11 | 1024 | 925 | 9.7 | 204 | 99 | 48.5 | D | C | ∘ |
| Comparative Example 12 | 1025 | 940 | 8.3 | 205 | 118 | 57.6 | D | C | ∘ |

### Example 31

Under a yellow lamp, the respective ingredients according to the list of ratios shown in Table 7 were mixed and stirred to obtain a homogeneous solution and the resulting solution was then filtered through a 0.20-μm filter to prepare a composition 31.

Immediately after the preparation of the composition 31, the composition was applied on a silicon wafer of 4 inch in diameter by spin coating using a spin coater (1H-360S; manufactured by Mikasa Co., Ltd.) and then heated at 100° C. for 3 minutes by using a hot plate (SCW-636; manufactured by Dainippon Screen Mfg. Co., Ltd.) to produce a pre-baked film with a film thickness of 1.0 μm. The entire surface of the obtained pre-baked film was exposed to i-line light with an i-line stepper (i9C; manufactured by Nikon Corporation) for 1000 msec. After exposure to light, the film was developed in a shower of 2.38% by weight TMAH in water for 60 seconds by using an automatic developing machine (AD-2000; manufactured by Takizawa Sangyo Co., Ltd.) and then rinsed in water for 30 seconds to obtain a developed film. Subsequently, the developed film was cured at 220° C. for 5 minutes by using a hot plate to produce a cured film 1.

Moreover, the obtained pre-baked film was exposed to i-line light with an i-line stepper for a time period ranging from 100 to 1000 msec with an increment of 50 msec and then developed and cured by the same procedures as described above to obtain a cured film 2.

Moreover, the prepared composition 31 was applied on the rugged substrate shown in FIG. 5 and FIG. 6 and then pre-baked, developed and cured by the same procedures as described above to obtain a cured film 3 with a d_{TOP} length of 0.3

The cured film 1 was used to measure (1) the refractive index and (2) the transmittance, and the cured film 2 was used to evaluate (3) the resolution and (4) the residue, and the cured film 3 was used to evaluate the flatness. The evaluation methods for (1) to (4) will be described below. The composition 31 was further used to separately measure the film thickness values X′ and Y according to the above-described procedures and the shrinkage ratio was then calculated. These results are presented in Table 9.

### (1) Measurement of Refractive Index

The obtained cured film was measured for refractive index at 633 nm at 22° C. by using the FE-5000 spectrum ellipsometer manufactured by Otsuka Electronics Co., Ltd.

### (2) Measurement of Transmittance (at a Wavelength of 400 nm; Per 1 μm Thickness)

The extinction coefficient of the obtained cured film at a wavelength of 400 nm was measured by the FE-5000 spectrum ellipsometer manufactured by Otsuka Electronics Co., Ltd. The light transmittance (%) per 1 μm film thickness at a wavelength of 400 nm was obtained by the following formula:

Light transmittance=exp(−4πkt/λ)

In the above formula, k represents the extinction coefficient, t represents the converted film thickness (μm), and λ represents the wavelength used for the measurement (nm). In the present measurement, the light transmittance per 1 μm film thickness is to be obtained and t is thus 1 (μm).

### (3) Resolution

The obtained cured film 2 for every exposure dose was observed for square patterns and the smallest pattern dimension was considered as the resolution. The evaluation criterion was defined as follows:

A: the smallest pattern dimension x satisfies x<15 μm;
B: the smallest pattern dimension x satisfies 15 μm≤x<50 μm;
C: the smallest pattern dimension x satisfies 50 μm≤x<100 μm;
D: the smallest pattern dimension x satisfies 100 μm≤x.

### (4) Residue

The extent of undissolution of film on the unexposed portion was evaluated in the obtained cured film 2 as follows:

5: Undissolution of film is visually unobservable and no undissolved residue is observed even on a fine pattern with a width of not more than 50 μm under microscopy;
4: Undissolution of film is visually unobservable and any undissolved residue is not observed on a pattern with a width of more than 50 μm but observed on a pattern with a width of not more than 50 μm under microscopy;
3: Undissolution of film is visually unobservable but an undissolved residue is observed on a pattern with a width of more than 50 μm under microscopy;
2: Undissolution of film is visually observable at the periphery of the substrate (the thick film portion);
1: Undissolution of film is visually observable on the entire region of the unexposed portion.

### Examples 32 to 44

The compositions 31 to 44 having the compositions shown in Table 7 were prepared similarly to the composition 31. The respective obtained compositions were used similarly to Example 31 to produce pre-baked films and cured films 1 to 3 and then to evaluate those cured films. The evaluation results are presented in Table 9.

Any pre-baked film which was entirely dissolved during the development and was not available for the calculation of the refractive index (1) and the measurement of the transmittance (2) was processed similarly to Example 31 except for the development to produce cured films and then to evaluate those cured films.

### Comparative Examples 13 to 17

The comparative compositions 13 to 17 having the compositions shown in Table 8 were prepared similarly to the composition 31. The respective obtained compositions were used similarly to Example 31 to produce pre-baked films and cured films 1 to 3 and then to evaluate those cured films. The evaluation results are presented in Table 9.

Any pre-baked film which was entirely dissolved during the development and was not available for the calculation of the refractive index (1) and the measurement of the transmittance (2) was processed similarly to Example 31 except for the development to produce cured films and then to evaluate those cured films.

TABLE 7

| | | | | Compound | | | |
|---|---|---|---|---|---|---|---|
| | | | | having a radical | | | |
| | | | | polymenzable | | | |
| | Name of a | | | group and an | | | |
| | resin | Polysiloxane | Ratio | aromatic ring | Ratio | Photosensitizer | Ratio |
| No. | composition | (A) | (wt %) | (B) | (wt %) | ( C) | (wt %) |
| Example 31 | Composition 31 | P-22 | 8 | BP-4EA | 4.4 | OXE01 | 0.8 |
| Example 32 | Composition 32 | P-23 | 8 | BP-4EA | 4.4 | OXE01 | 0.8 |
| Example 33 | Composition 33 | P-24 | 8 | BP-4EA | 4.4 | OXE01 | 0.8 |
| Example 34 | Composition 34 | P-25 | 8 | BP-4EA | 4.4 | OXE01 | 0.8 |
| Example 35 | Composition 35 | P-26 | 8 | BP-4EA | 4.4 | OXE01 | 0.8 |
| Example 36 | Composition 36 | P-27 | 8 | BP-4EA | 4.4 | OXE01 | 0.8 |
| Example 37 | Composition 37 | P-28 | 8 | BP-4EA | 4.4 | OXE01 | 0.8 |
| Example 38 | Composition 38 | P-29 | 8 | BP-4EA | 4.4 | OXE01 | 0.8 |
| Example 39 | Composition 39 | P-30 | 8 | BP-4EA | 4.4 | OXE01 | 0.8 |
| Example 40 | Composition 40 | P-31 | 8 | BP-4EA | 4.4 | OXE01 | 0.8 |
| Example 41 | Composition 41 | P-32 | 8 | BP-4EA | 4.4 | OXE01 | 0.8 |
| Example 42 | Composition 42 | P-22 | 8 | BP-4EA | 2.2 | OXE01 | 0.8 |
| | | | | EA-250P | 2.2 | | |
| Example 43 | Composition 43 | P-22 | 8 | EA-250P | 4.4 | OXE01 | 0.8 |
| Example 44 | Composition 44 | P-22 | 8 | BP-4EA | 4.4 | OXE01 | 0.8 |

| | Metal | | | | | |
|---|---|---|---|---|---|---|
| | compound | | | | | |
| | particles | Ratio | Solvent | Ratio | | Ratio |
| No. | (D) | (wt %) | (E) | (wt %) | Others | (wt %) |
| Example 31 | D-1 | 9.7 | DAA/CP/PGME | 30.8/23.1/23.1 | t-butylpyrocatechol/ | 0.1/150 |
| | | | | | BYK-333 | ppm |
| Example 32 | D-1 | 9.7 | DAA/CP/PGME | 30.8/23.1/23.1 | t-butylpyrocatechol/ | 0.1/150 |
| | | | | | BYK-333 | ppm |
| Example 33 | D-1 | 9.7 | DAA/CP/PGME | 30.8/23.1/23.1 | t-butylpyrocatechol/ | 0.1/150 |
| | | | | | BYK-333 | ppm |
| Example 34 | D-1 | 9.7 | DAA/CP/PGME | 30.8/23.1/23.1 | t-butylpyrocatechol/ | 0.1/150 |
| | | | | | BYK-333 | ppm |
| Example 35 | D-1 | 9.7 | DAA/CP/PGME | 30.8/23.1/23.1 | t-butylpyrocatechol/ | 0.1/150 |
| | | | | | BYK-333 | ppm |
| Example 36 | D-1 | 9.7 | DAA/CP/PGME | 30.8/23.1/23.1 | t-butylpyrocatechol/ | 0.1/150 |
| | | | | | BYK-333 | ppm |
| Example 37 | D-1 | 9.7 | DAA/CP/PGME | 30.8/23.1/23.1 | t-butylpyrocatechol/ | 0.1/150 |
| | | | | | BYK-333 | ppm |
| Example 38 | D-1 | 9.7 | DAA/CP/PGME | 30.8/23.1/23.1 | t-butylpyrocatechol/ | 0.1/150 |
| | | | | | BYK-333 | ppm |
| Example 39 | D-1 | 9.7 | DAA/CP/PGME | 30.8/23.1/23.1 | t-butylpyrocatechol/ | 0.1/150 |
| | | | | | BYK-333 | ppm |
| Example 40 | D-1 | 9.7 | DAA/CP/PGME | 30.8/23.1/23.1 | t-butylpyrocatechol/ | 0.1/150 |
| | | | | | BYK-333 | ppm |
| Example 41 | D-1 | 9.7 | DAA/CP/PGME | 30.8/23.1/23.1 | t-butylpyrocatechol/ | 0.1/150 |
| | | | | | BYK-333 | ppm |
| Example 42 | D-1 | 9.7 | DAA/CP/PGME | 30.8/23.1/23.1 | t-butylpyrocatechol/ | 0.1/150 |
| | | | | | BYK-333 | ppm |
| Example 43 | D-1 | 9.7 | DAA/CP/PGME | 30.8/23.1/23.1 | t-butylpyrocatechol/ | 0.1/150 |
| | | | | | BYK-333 | ppm |
| Example 44 | D-2 | 9.7 | DAA/PGMEA | 46.2/30.8 | t-butylpyrocatechol/ | 0.1/150 |
| | | | | | BYK-333 | ppm |

TABLE 8

| | | | | Compound | | | |
|---|---|---|---|---|---|---|---|
| | | | | having a radical | | | |
| | | | | polymerizable | | | |
| | Name of a | | | group and an | | | |
| | resin | Polysiloxane | Ratio | aromatic ring | Ratio | Photosensitizer | Ratio |
| No. | composition | (A) | (wt %) | (B) | (wt %) | (C) | (wt %) |
| Comparative | Comparative | P-14 | 8 | BP-4EA | 4.4 | OXE01 | 0.8 |
| Example 13 | Composition 13 | | | | | | |
| Comparative | Comparative | R-8 | 8 | BP-4EA | 4.4 | OXE01 | 0.8 |
| Example 14 | Composition 14 | | | | | | |
| Comparative | Comparative | R-9 | 8 | BP-4EA | 4.4 | OXE01 | 0.8 |
| Example 15 | Composition 15 | | | | | | |
| Comparative | Comparative | R-10 | 8 | BP-4EA | 4.4 | OXE01 | 0.8 |
| Example 16 | Composition 16 | | | | | | |
| Comparative | Comparative | R-3 | 8 | DPHA/BPEFA | 6.8/6.8 | IC907/4,4- | 2.6/0.1 |
| Example 17 | Composition 17 | | | | | bis(diethylamino) | |
| | | | | | | benzophenone | |

| | Metal | | | | | |
|---|---|---|---|---|---|---|
| | compound | | Solvent | | | |
| | particles | Ratio | (E) | Ratio | | Ratio |
| No. | (D) | (wt %) | (wt %) | (wt %) | Others | (wt %) |
| Comparative | D-1 | 9.7 | DAA/CP/PGME | 30.8/23.1/23.1 | t-butylpyrocatechol/ | 0.1/150 |
| Example 13 | | | | | BYK-333 | ppm |
| Comparative | D-1 | 9.7 | DAA/CP/PGME | 30.8/23.1/23.1 | t-butylpyrocatechol/ | 0.1/150 |
| Example 14 | | | | | BYK-333 | ppm |
| Comparative | D-1 | 9.7 | DAA/CP/PGME | 30.8/23.1/23.1 | t-butylpyrocatechol/ | 0.1/150 |
| Example 15 | | | | | BYK-333 | ppm |
| Comparative | D-1 | 9.7 | DAA/CP/PGME | 30.8/23.1/23.1 | t-butylpyrocatechol/ | 0.1/150 |
| Example 16 | | | | | BYK-333 | ppm |
| Comparative | D-1 | 9.7 | DAA/PGMEA | 35/35 | t-butylpyrocatechol/ | 0.1/150 |
| Example 17 | | | | | BYK-333 | ppm |

TABLE 9

| | Film | Film | | | | | | | | |
|---|---|---|---|---|---|---|---|---|---|---|
| | thickness | thickness | Shrinkage | | | | | | | |
| | X′ | Y | ratio | | Refractive index at | | Transmittance at | | | |
| | (nm) | (nm) | (%) | Flatness | 633 nm | | 400 nm | | Resolution | Residue |
| Example 31 | 1002 | 966 | 3.7 | A | 1.69 | B | 97.3 | B | B | 4 |
| Example 32 | 1006 | 980 | 2.7 | A | 1.71 | B | 95.4 | B | B | 3 |
| Example 33 | 1010 | 970 | 4.1 | B | 1.66 | B | 98.2 | A | A | 5 |
| Example 34 | 1001 | 960 | 4.3 | B | 1.66 | B | 98.0 | A | A | 4 |
| Example 35 | 1002 | 971 | 3.2 | A | 1.71 | B | 96.3 | B | B | 4 |
| Example 36 | 1007 | 976 | 3.2 | A | 1.71 | B | 95.6 | B | B | 4 |
| Example 37 | 1002 | 966 | 3.7 | A | 1.69 | B | 97.5 | B | B | 5 |
| Example 38 | 1004 | 967 | 3.8 | A | 1.69 | B | 97.1 | B | B | 3 |
| Example 39 | 1001 | 964 | 3.8 | A | 1.69 | B | 97.0 | B | A | 4 |
| Example 40 | 1003 | 972 | 3.2 | A | 1.71 | B | 96.1 | B | A | 4 |
| Example 41 | 1011 | 974 | 3.8 | A | 1.8 | A | 96.4 | B | B | 5 |
| Example 42 | 1004 | 968 | 3.7 | A | 1.69 | B | 97.1 | B | B | 4 |
| Example 43 | 1006 | 969 | 3.8 | A | 1.69 | B | 97.0 | B | B | 3 |
| Example 44 | 1001 | 965 | 3.7 | A | 1.69 | B | 97.3 | B | B | 4 |
| Comparative Example 13 | 999 | 960 | 4.1 | B | 1.69 | B | 97.4 | B | D | 2 |
| Comparative Example 14 | 1012 | 923 | 9.6 | D | 1.68 | B | 97.2 | B | C | 3 |
| Comparative Example 15 | 1007 | 910 | 10.7 | D | 1.55 | D | 98.5 | A | B | 4 |
| Comparative Example 16 | 1009 | 976 | 3.4 | A | 1.69 | B | 97.4 | B | B | 1 |
| Comparative Example 17 | 1011 | 915 | 10.5 | D | 1.53 | D | 95.8 | B | A | 4 |

Comparison of Examples 1 to 21 with Comparative Examples 1 to 7 and 9 to 12 indicates that the resin compositions according to an embodiment of the present invention are compositions with low film shrinkage and excellent flatness. In Comparative Example 8, the film exhibited relatively low shrinkage and achieved acceptable flatness but had a poor storage stability and showed an increase in viscosity during storage. Thus, the comparative composition of this Comparative Example was considered to be inferior to the resin compositions according to an embodiment of the present invention.

Comparison of Examples 1 to 5 with Comparative Examples 6, 7 and 9 indicates that the presence of styryl groups in a polysiloxane significantly reduces the shrinkage ratio and improves the flatness.

Moreover, comparison of Examples 9 to 12 and 16 to 21 with Comparative Examples 5, 11 and 12 indicates that the presence of more styryl groups results in a lower film shrinkage ratio and an improved flatness. In particular, the content of styryl groups in the range of 40 to 99% by mole relative to 100% by mole of the Si atoms resulted in excellent flatness as shown in Examples 9 to 12 and 16 to 21.

Comparison of Examples 1 to 21 with Comparative Examples 10 to 12 indicates that the presence of a further hydrophilic group in a siloxane containing a styryl group results in significantly improved coating properties.

Furthermore, the results from Examples 31 to 41 indicate that the addition of the ingredient (B), the ingredient (C), and the ingredient (D) allows obtaining photosensitive resin compositions from which cured films with a high refractive index and excellent flatness can be prepared. Comparison of Examples 31 to 41 with Comparative Example 13 indicates that the presence of (meth)acryloyl groups in those photosensitive resin compositions results in improved photosensitive properties such as resolution and residue. Moreover, comparison of Examples 31 to 41 with Comparative Examples 14, 15 and 17 indicates that the presence of styryl groups contributes to the reduction in film shrinkage ratio and the improvement in flatness. Furthermore, comparison of Examples 31 to 41 with Comparative Example 16 indicates that the presence of hydrophilic groups contributes to the photosensitive properties.

### REFERENCE SIGNS LIST

1. Patterned portion
2. Support substrate
3. Resin film prior to curing
4. Resin film post curing
5. Cured film pattern
6. Silicon wafer
7. Substrate
8. Coated film
9. Mask
10. Activating light
11. Pattern
12. Cured film
13. Second coated film
14. Pattern
15. Cured film

1. A resin composition comprising a polysiloxane (A), wherein the polysiloxane (A) contains at least one partial structure represented by any of the general formulae (1) to (3), and the molar content of styryl groups contained in the polysiloxane (A) is in the range of not less than 40% by mole to not more than 99% by mole relative to 100% by mole of the Si atoms: 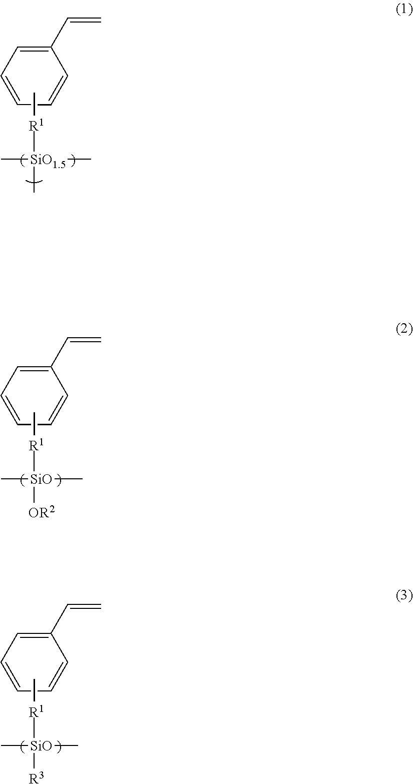
(wherein R¹ represents a single bond or a C₁₋₄ alkylene group; R² represents a hydrogen atom or a C₁₋₄ alkyl group; and R³ represents an organic group).

2. The resin composition according to claim 1, wherein the polysiloxane (A) further contains at least one partial structure represented by any of the following general formulae (7) to (9): 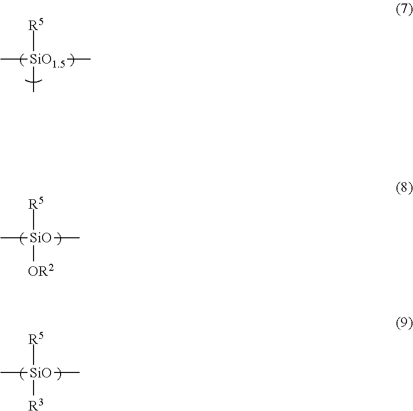
(wherein R⁵ represents a hydrocarbon group having an epoxy group, urea group, urethane group, amide group, hydroxyl group, carboxyl group, or carboxylic anhydride; R² represents a hydrogen atom or a C₁₋₄ alkyl group; and R³ represents an organic group).

3. The resin composition according to claim 2, wherein the polysiloxane (A) further contains at least one partial structure represented by any of the following general formulae (4) to (6): 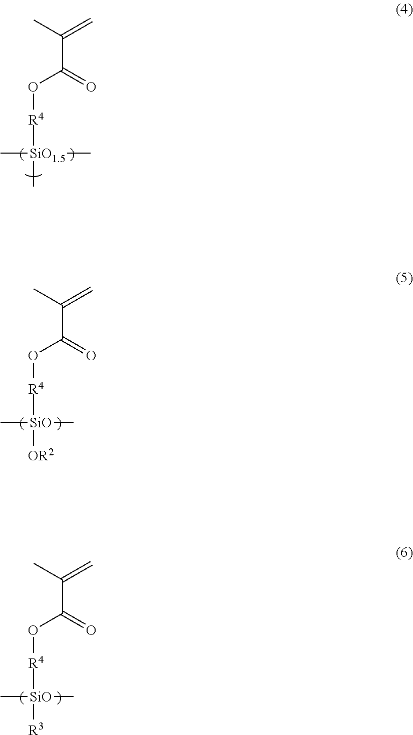
(wherein R⁴ each independently represents a single bond or a C₁₋₄ alkylene group; R² represents a hydrogen atom or a C₁₋₄ alkyl group; and R³ represents an organic group).

4. The resin composition according to claim 1, wherein the rate of film thickness change in the resin composition before and after heating at 230° C. for 5 minutes is not more than 5%.

5. (canceled)

6. The resin composition according to claim 1, which comprises metal compound particles (D).

7. The resin composition according to claim 1, wherein the polysiloxane (A) contains styryl group (a-1), (meth)acryloyl group (a-2) and a hydrophilic group (a-3), and wherein the resin composition further comprises a compound having a radical polymerizable group and an aromatic ring (B).

8. The resin composition according to claim 7, wherein the molar contents of styryl groups (a-1) and (meth)acryloyl groups (a-2) in the polysiloxane (A) are, respectively, in the range of not less than 45% by mole to not more than 70% by mole and not less than 15% by mole to not more than 40% by mole relative to 100% by mole of the Si atoms.

9. The resin composition according to claim 7, wherein the hydrophilic group (a-3) is a hydrocarbon group having a structure based on succinic acid or succinic anhydride and the molar content of the hydrophilic groups (a-3) in the polysiloxane (A) is in the range of not less than 10% by mole to not more than 20% by mole relative to 100% by mole of the Si atoms.

10. The resin composition according to claim 7, which contains:
the polysiloxane (A) in a ratio of not less than 20% by weight and not more than 50% by weight, the compound having a radical polymerizable group and an aromatic ring (B) in a ratio of not less than 5% by weight and not more than 35% by weight,
a photosensitizer (C) in a ratio of not less than 1% by weight and not more than 10% by weight, and
the metal compound particles (D) in a ratio of not less than 30% by weight and not more than 60% by weight.

11. A method of manufacturing a cured film, the method comprising the steps of:
(I) applying the resin composition according to claim 7 on a substrate to prepare a coated film;
(II) exposing the coated film to light and developing the exposed film;
(IV) further applying the resin composition on the developed coated film to prepare a second coated film;
(V) exposing the second coated film to light and developing the exposed film; and
(VI) heating the developed coated film and the developed second coated film.

12. A method of manufacturing a cured film, the method comprising the steps of:
(I) applying the resin composition according to claim 7 on a substrate to prepare a coated film;
(II) exposing the coated film to light and developing the exposed film;
(III) heating the developed coated film;
(IV′) further applying the resin composition on the heated coated film to prepare a second coated film;
(V′) exposing the second coated film to light and developing the exposed film; and
(VI′) heating the developed second coated film.

13. A cured film of the resin composition according to claim 1.

14. A solid-state image sensor comprising the cured film according to claim 13.

15. The solid-state image sensor according to claim 14, wherein the cured film is an optical waveguide.

16. A resin composition comprising a polysiloxane (A), wherein the polysiloxane (A) is a polysiloxane that is obtainable by hydrolysis and polycondensation of plural alkoxysilane compounds including those represented by the following general formulae (10) and (11): 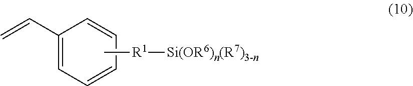
(wherein R¹ represents a single bond or a C₁₋₄ alkyl group; R⁷ represents a C₁₋₄ alkyl group; R⁶ represents an organic group, and n is 2 or 3); 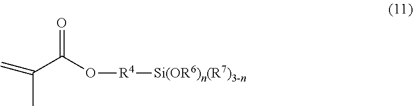
(wherein R⁴ represents an epoxy group, urea group, urethane group, amido group, hydroxyl group, carboxyl group, or hydrocarbon group having a structure based on a carboxylic anhydride; R⁷ represents a C₁₋₄ alkyl group; R⁶ represents an organic group, and n is 2 or 3).

17. The resin composition according to claim 16, which comprises metal compound particles (D).

18. The resin composition according to claim 16, wherein the polysiloxane (A) contains styryl group (a-1), (meth)acryloyl group (a-2) and a hydrophilic group (a-3), and wherein the resin composition further comprises a compound having a radical polymerizable group and an aromatic ring (B).

19. The resin composition according to claim 18, wherein the molar contents of styryl groups (a-1) and (meth)acryloyl groups (a-2) in the polysiloxane (A) are, respectively, in the range of not less than 45% by mole to not more than 70% by mole and not less than 15% by mole to not more than 40% by mole relative to 100% by mole of the Si atoms.

20. The resin composition according to claim 18, wherein the hydrophilic group (a-3) is a hydrocarbon group having a structure based on succinic acid or succinic anhydride and the molar content of the hydrophilic groups (a-3) in the polysiloxane (A) is in the range of not less than 10% by mole to not more than 20% by mole relative to 100% by mole of the Si atoms.

21. The resin composition according to claim 18, which contains:
the polysiloxane (A) in a ratio of not less than 20% by weight and not more than 50% by weight, the compound having a radical polymerizable group and an aromatic ring (B) in a ratio of not less than 5% by weight and not more than 35% by weight,
a photosensitizer (C) in a ratio of not less than 1% by weight and not more than 10% by weight, and
the metal compound particles (D) in a ratio of not less than 30% by weight and not more than 60% by weight.

22. A method of manufacturing a cured film, the method comprising the steps of:
(I) applying the resin composition according to claim 18 on a substrate to prepare a coated film;
(II) exposing the coated film to light and developing the exposed film;
(IV) further applying the resin composition on the developed coated film to prepare a second coated film;
(V) exposing the second coated film to light and developing the exposed film; and
(VI) heating the developed coated film and the developed second coated film.

23. A method of manufacturing a cured film, the method comprising the steps of:
(I) applying the resin composition according to claim 18 on a substrate to prepare a coated film;
(II) exposing the coated film to light and developing the exposed film;
(III) heating the developed coated film;
(IV′) further applying the resin composition on the heated coated film to prepare a second coated film;
(V′) exposing the second coated film to light and developing the exposed film; and
(VI′) heating the developed second coated film.

24. A cured film of the resin composition according to claim 16.

25. A solid-state image sensor comprising the cured film according to claim 24.

26. The solid-state image sensor according to claim 25, wherein the cured film is an optical waveguide.
